(19) United States
(12) Patent Application Publication
(10) Pub. No.: US 2026/0290750 A1
(43) Pub. Date: Sep. 24, 2026

(54) ION IMPLANTER AND ANGLE MEASUREMENT DEVICE

(71) Applicant: Sumitomo Heavy Industries Material Solutions Co., Ltd., Tokyo (JP)

(72) Inventor: Yoshiaki INDA, Ehime (JP)

(21) Appl. No.: 19/681,358

(22) Filed: May 19, 2026

Related U.S. Application Data
(63) Continuation of application No. PCT/JP2024/040966, filed on Nov. 19, 2024.

(30) Foreign Application Priority Data
Dec. 21, 2023 (JP) 2023-215840

(51) Int. Cl. H01J 37/317

(52) U.S. Cl. CPC H01J 37/3171

(57) ABSTRACT

An ion implanter includes a beam scanner configured to perform reciprocating scanning with an ion beam to generate a scanning beam, and an angle measurement device that measures angle information of the scanning beam, in which the angle measurement device includes an incidence surface including a first incidence opening into which the scanning beam is incident, an emission surface provided with a first emission opening, an electrode assembly provided between the incidence surface and the emission surface and including a first electrode surface and a second electrode surface, a power supply that applies a voltage to the electrode assembly to generate a potential difference between the first electrode surface and the second electrode surface, and a current measurement device that detects the ion beam that has passed through the first emission opening to measure a beam current value.

### CROSS-REFERENCE TO RELATED APPLICATIONS

This is a bypass continuation of International PCT Application No. PCT/JP2024/040966, filed on Nov. 19, 2024, which claims priority to Japanese Patent Application No. 2023-215840, filed on Dec. 21, 2023, which are incorporated by reference herein in their entirety.

### BACKGROUND

### Technical Field

Certain embodiments of the present invention relate to an ion implanter and an angle measurement device.

### Description of Related Art

In a semiconductor device manufacturing process, a process of implanting ions into a semiconductor wafer (also referred to as an ion implantation process) is generally performed in order to change the conductivity of a semiconductor, and in order to change a crystal structure of the semiconductor. It is known that an aspect of an interaction between the ion beam and the wafer changes depending on an angle of the ion beam to be irradiated to the wafer, and the angle information of the ion beam is measured before the ion implantation. For example, the angle information in the slit width direction can be obtained by measuring a current value of the beam passing through the slit with a plurality of electrode bodies arranged in the slit width direction (for example, refer to the related art).

### SUMMARY

One or more embodiments provide an ion implanter including a beam scanner configured to perform reciprocating scanning in a predetermined scanning direction with an ion beam to generate a scanning beam, and an angle measurement device that measures angle information of the scanning beam. The angle measurement device includes an incidence surface including a first incidence opening into which the scanning beam is incident, an emission surface provided with a first emission opening from which an ion beam that has passed through the first incidence opening is emitted, an electrode assembly provided between the incidence surface and the emission surface and including a first electrode surface and a second electrode surface that face each other in a first direction across an ion beam directed from the first incidence opening toward the first emission opening, a power supply that applies a voltage to the electrode assembly to generate a potential difference between the first electrode surface and the second electrode surface, and a current measurement device that detects the ion beam that has passed through the first emission opening to measure a beam current value.

One or more embodiments provide an angle measurement device including an incidence surface that includes a first incidence opening and a second incidence opening into which an ion beam is incident, an emission surface that includes a first emission opening from which an ion beam that has passed through the first incidence opening is emitted and a second emission opening from which an ion beam that has passed through the second incidence opening is emitted, an electrode assembly that is provided between the incidence surface and the emission surface, and that includes a first electrode surface and a second electrode surface that face each other in a first direction across an ion beam directed from the first incidence opening toward the first emission opening, and a third electrode surface and a fourth electrode surface that face each other in a second direction across an ion beam directed from the second incidence opening toward the second emission opening, and that includes an electrode body including the second electrode surface and the third electrode surface, a power supply that applies a voltage to the electrode assembly to generate a potential difference between the first electrode surface and the second electrode surface, and a potential difference between the third electrode surface and the fourth electrode surface, and a current measurement device that detects at least one of an ion beam that has passed through the first emission opening and an ion beam that has passed through the second emission opening to measure a beam current value.

### BRIEF DESCRIPTION OF THE DRAWINGS

FIG. 1 is a top view illustrating a schematic configuration of an ion implanter, according to an embodiment.

FIG. 2 is a side view showing the schematic configuration of the ion implanter, according to the embodiment.

FIG. 3 is a front view showing a schematic configuration of a first holding device and a second holding device.

FIGS. 4A and 4B are top views schematically showing a horizontal orientation of a first workpiece held by the first holding device.

FIGS. 5A to 5C are side views schematically showing an orientation of the first workpiece, which is held by the first holding device, in a vertical direction.

FIG. 6 is a front view showing an example of the operations of the first holding device and the second holding device.

FIG. 7 is a front view showing an example of the operations of the first holding device and the second holding device.

FIG. 8 is a front view showing an example of the operations of the first holding device and the second holding device.

FIG. 9 is a front view showing an example of the operations of the first holding device and the second holding device.

FIG. 10 is a flowchart illustrating a flow of an ion implantation method, according to the embodiment.

FIG. 11 is a flowchart showing a flow of an ion implantation method according to a modification example.

FIG. 12 is a top view showing a schematic configuration of an ion implanter, according to another embodiment.

FIG. 13 is a side view showing a schematic configuration of an ion implanter, according to another embodiment.

FIG. 14 is a front view schematically showing a movable range of a beam profiler.

FIG. 15 is a cross-sectional view showing a schematic configuration of an angle measurement device, according to a first embodiment.

FIG. 16A is a plan view showing a schematic configuration of an incidence surface having an incidence opening, and FIG. 16B is a plan view showing a schematic configuration of an emission surface having an emission opening.

FIG. 17 is a graph showing an example of a time waveform of a scanning voltage waveform of the scanning beam and a potential difference in the angle measurement device.

FIG. 18A is a graph showing an example of a time waveform of a beam current detected by the angle measurement device, and FIG. 18B is a graph showing an example of an angle distribution of the scanning beam calculated using the time waveform of the beam current of FIG. 18A.

FIG. 19 is a plan view showing a schematic configuration of an incidence surface of an angle measurement device, according to a second embodiment.

FIG. 20 is a plan view showing a schematic configuration of an emission surface of the angle measurement device, according to the second embodiment.

FIG. 21 is a cross-sectional view showing a schematic configuration of an electrode assembly, according to the second embodiment.

FIG. 22 is a plan view showing a schematic configuration of a current measurement device, according to the second embodiment.

FIG. 23 is a cross-sectional view showing a schematic configuration of an electrode assembly, according to the modification example.

FIG. 24 is a plan view showing a schematic configuration of an incidence surface of an angle measurement device, according to a third embodiment.

FIG. 25 is a plan view showing a schematic configuration of an emission surface of the angle measurement device, according to the third embodiment.

FIG. 26 is a cross-sectional view showing a schematic configuration of an electrode assembly, according to the third embodiment.

FIG. 27 is a plan view showing a schematic configuration of a current measurement device, according to the third embodiment.

FIG. 28 is a cross-sectional view showing a schematic configuration of an electrode assembly, according to the modification example.

### DETAILED DESCRIPTION

In recent years, there is a demand for more precise control of an ion beam implantation angle condition in the ion implantation, and it is preferable to measure the angle information of the ion beam with higher resolution. However, in a case in which the angle information of the ion beam is measured using a plurality of electrode bodies, in order to increase the resolution of the angle information, the number of the plurality of electrode bodies needs to be increased and the width of each electrode body in the angle measurement direction needs to be reduced. Therefore, the manufacturing difficulty of the angle measurement device increases, which leads to an increase in cost. In addition, in a case in which the width of each electrode body in the angle measurement direction is reduced, the beam current of the ion beam detected by each electrode body is also reduced, and the detection of the ion beam is likely to be affected by noise.

According to the present disclosure, it is possible to provide a technique for accurately and quickly measuring the angle information of the ion beam.

Any combination of the above-described components, and those in which components or expressions according to the present disclosure are substituted from each other in methods, devices, or systems are effectively applicable as an aspect of the present disclosure.

Embodiments of an ion implanter and an ion implantation method according to the present disclosure will be described in detail below with reference to the drawings. In describing the drawings, the same reference numerals will be assigned to the same elements, and repeated description will be appropriately omitted. In addition, configurations described below are merely examples, and do not limit the scope of the present disclosure in any way.

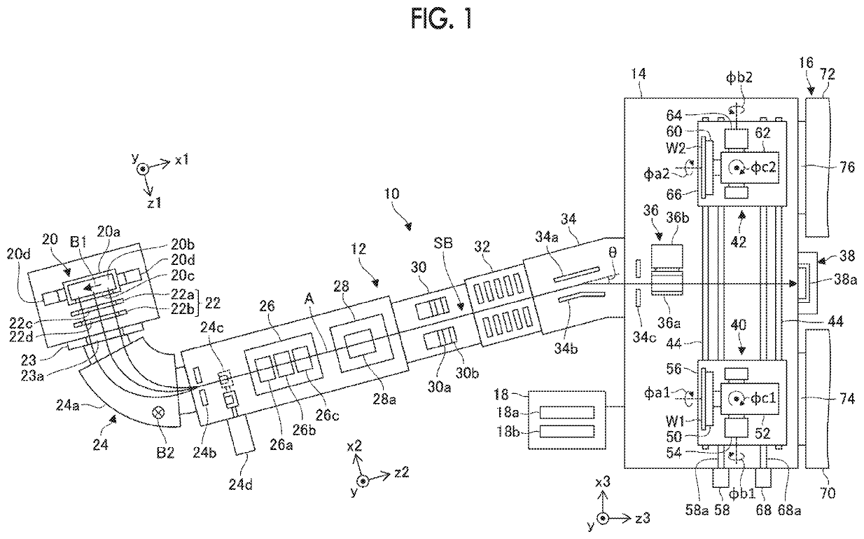

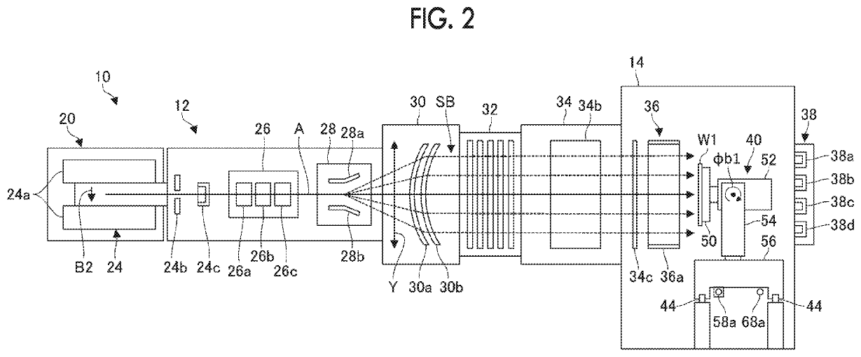

FIG. 1 is a top view showing a schematic configuration of an ion implanter 10 according to the embodiment. FIG. 2 is a side view showing the schematic configuration of the ion implanter 10 according to the embodiment. The ion implanter 10 is configured to perform an ion implantation process on surfaces of workpieces W1 and W2. The workpieces W1 and W2 are, for example, substrates, and are, for example, semiconductor wafers. For convenience of description, the workpiece is referred to as a “substrate” or a “wafer” in the present specification. However, this is not intended to limit a workpiece to the implantation processing to a specific object. The workpiece may be a large substrate (for example, a glass substrate or a resin substrate) used to manufacture a flat panel display (FPD).

The ion implanter 10 is configured to irradiate the entire processing target surfaces of the workpieces W1 and W2 with a spot-like ion beam by performing reciprocating scanning in a predetermined scanning direction with the ion beam and reciprocating the workpieces W1 and W2 in a direction intersecting the scanning direction. The ion implanter 10 includes a beam generator 12, an implantation processing chamber 14, a transport device 16, and a controller 18.

The beam generator 12 is configured to generate an ion beam and to transport the ion beam to the implantation processing chamber 14. The implantation processing chamber 14 accommodates the workpieces W1 and W2 that are the targets of the implantation process. In the implantation processing chamber 14, the workpieces W1 and W2 are irradiated with the ion beam provided from the beam generator 12. The transport device 16 is configured to transport the workpieces W1 and W2 before the implantation process into the implantation processing chamber 14 and to transport the workpieces W1 and W2 after the implantation process from the implantation processing chamber 14. The controller 18 is configured to control the overall operation of various devices constituting the ion implanter 10. The ion implanter 10 includes a vacuum evacuation system (not shown) for providing a desired vacuum environment to the beam generator 12, the implantation processing chamber 14, and the transport device 16.

The beam generator 12 includes an ion source 20, an extractor 22, a mass spectrometry unit 24, a beam shaping unit 26, a beam scanner 28, a beam parallelizing unit 30, an acceleration/deceleration unit 32, and an energy filter 34 in order from an upstream side of a beamline A. Here, the beamline A is used for convenience of description, and is synonymous with a beam trajectory ideal in design in a case where the workpieces are not scanned with an ion beam by the beam scanner 28. Further, an upstream of the beamline A refers to a side close to the ion source 20, and a downstream of the beamline A refers to a side close to the implantation processing chamber 14 (or a beam stopper 38).

The beam generator 12 is configured such that the beamline A is bent in the middle. A traveling direction of the beamline A is changed in the mass spectrometry unit 24 and the energy filter 34. The beamline A is formed to extend in a horizontal plane perpendicular to a vertical direction. In the present specification, for convenience of description, a traveling direction of an ion beam traveling along the beamline A is defined as a z direction, the vertical direction is defined as a y direction, and a direction perpendicular to the y direction and the z direction is defined as an x direction. In particular, a traveling direction of the beamline A from the ion source 20 to the mass spectrometry unit 24 is defined as a z1 direction, and a direction perpendicular to the y direction and the z1 direction is defined as an x1 direction. Further, a traveling direction of the beamline A from the mass spectrometry unit 24 to the energy filter 34 is defined as a z2 direction, and a direction perpendicular to the y direction and the z2 direction is defined as an x2 direction. Furthermore, a traveling direction of the beamline A downstream of the energy filter 34 is defined as a z3 direction, and a direction perpendicular to the y direction and the z3 direction is defined as an x3 direction.

The ion source 20 is configured to generate ions that form an ion beam. The ion source 20 includes an arc chamber 20a. The arc chamber 20a includes an internal space 20b in which plasma is generated. The arc chamber 20a has the shape of a substantially rectangular parallelepiped box that defines an internal space 20b. The arc chamber 20a includes a front slit 20c for extracting ions from the plasma generated in the internal space 20b. The front slit 20c has the shape of a slit of which an opening width in a horizontal direction (x1 direction) is long and an opening width in the vertical direction (y direction) is short. That is, the opening width of the front slit 20c in the horizontal direction is larger than the opening width of the front slit 20c in the vertical direction.

The ion source 20 includes a source magnet device 20d. The source magnet device 20d is configured to apply a magnetic field B1, which is parallel to the horizontal direction (x1 direction), to the internal space 20b of the arc chamber 20a. The source magnet device 20d applies the magnetic field B1 to improve the generation efficiency of the plasma that is generated in the internal space 20b of the arc chamber 20a. A direction in which the magnetic field B1 is applied by the source magnet device 20d corresponds to a longitudinal direction of the front slit 20c.

The extractor 22 is provided downstream of the ion source 20. The extractor 22 extracts ions from the ion source 20 to generate the ion beam. The extractor 22 is configured to extract ions from the plasma generated in the internal space 20b of the arc chamber 20a. The extractor 22 includes a first extraction electrode 22a and a second extraction electrode 22b. The first extraction electrode 22a is provided on the downstream side of the arc chamber 20a, and the second extraction electrode 22b is provided on the downstream side of the first extraction electrode 22a. A negative suppression voltage is applied to the first extraction electrode 22a. A ground voltage is applied to the second extraction electrode 22b. A positive extraction voltage is applied to the arc chamber 20a.

The first extraction electrode 22a includes a first extraction opening 22c through which the ion beam passes. The first extraction opening 22c has the shape of a slit of which an opening width in the horizontal direction (x1 direction) is long and an opening width in the vertical direction (y direction) is short, like the front slit 20c. That is, the opening width of the first extraction opening 22c in the horizontal direction is larger than the opening width of the first extraction opening 22c in the vertical direction. The second extraction electrode 22b includes a second extraction opening 22d through which the ion beam passes. The second extraction opening 22d has the shape of a slit of which an opening width in the horizontal direction (x1 direction) is long and an opening width in the vertical direction (y direction) is short, like the front slit 20c. That is, the opening width of the second extraction opening 22d in the horizontal direction is larger than the opening width of the second extraction opening 22d in the vertical direction.

The ion beam extracted by the extractor 22 may be a ribbon-like beam that spreads in the horizontal direction (x1 direction). In a case where the opening widths of the front slit 20c, the first extraction opening 22c, and the second extraction opening 22d in the horizontal direction are increased, the size of the ribbon-like beam in the horizontal direction can be increased. As a result, it is easy to increase the beam current of the ion beam that is extracted from the ion source 20.

The mass spectrometry unit 24 is provided downstream of the extractor 22. The mass spectrometry unit 24 is configured to select a necessary ion species from the ion beam, which is extracted by the extractor 22, using mass spectrometry. The mass spectrometry unit 24 includes a mass spectrometry magnet device 24a, a mass resolving aperture 24b, and an injector Faraday cup 24c.

The mass spectrometry magnet device 24a applies a magnetic field B2 to the ion beam and deflects the ion beam along a different path according to a value of a mass-to-charge ratio (M=m/q, m is mass, and q is charge) of the ions. The mass spectrometry magnet device 24a applies the magnetic field B2, which is parallel to the vertical direction (−y direction), and deflects the ion beam in the horizontal direction (x1 direction). The intensity of the magnetic field B2 applied by the mass spectrometry magnet device 24a is adjusted such that an ion species having a desired mass-to-charge ratio M passes through the mass resolving aperture 24b. The ion beam passing through the mass resolving aperture 24 b is deflected by, for example, 90 degrees by the mass spectrometry magnet device 24a.

The mass resolving aperture 24b is provided downstream of the mass spectrometry magnet device 24a. The mass resolving aperture 24b has the shape of a slit of which an opening width in the horizontal direction (x2 direction) is short and an opening width in the vertical direction (y direction) is long. That is, the opening width of the mass resolving aperture 24b in the vertical direction is larger than the opening width of the mass resolving aperture 24b in the horizontal direction.

The mass resolving aperture 24b may be configured such that an opening width (that is, a slit width) in the horizontal direction (x2 direction) is variable to adjust a mass resolution. The mass resolving aperture 24b may be configured to include two beam shield members that are movable in a slit width direction, and may be configured such that the slit width can be adjusted with a change in an interval between the two beam shield members. The mass resolving aperture 24b may be configured such that the mass resolving aperture 24b is switched to any one of a plurality of slits having different slit widths to make the slit width variable.

The injector Faraday cup 24c is provided downstream of the mass resolving aperture 24b. The injector Faraday cup 24c measures the beam current of the ion beam that passes through the mass resolving aperture 24b and has been subjected to mass spectrometry. The injector Faraday cup 24c can measure a mass spectrometry spectrum of the ion beam by measuring the beam current while changing the intensity of the magnetic field of the mass spectrometry magnet device 24a. The measured mass spectrometry spectrum can be used to calculate the mass resolution of the mass spectrometry unit 24.

The injector Faraday cup 24c is configured to be movable into and out of the beamline A by an operation of an injector driver 24d. The injector driver 24d moves the injector Faraday cup 24c in a direction perpendicular to the z2 direction in which the beamline A extends (for example, the x2 direction). In a case where the injector Faraday cup 24c is disposed on the beamline A as shown by a broken line in FIG. 1, the injector Faraday cup 24c blocks the ion beam directed to the downstream side. On the other hand, in a case where the injector Faraday cup 24c retreats from the beamline A as shown by a solid line in FIG. 1, the blocking of the ion beam directed to the downstream side is released.

A magnetic shield 23 may be provided between the extractor 22 and the mass spectrometry unit 24. The magnetic shield 23 is configured to suppress magnetic field interference between the magnetic field B1 applied to the ion source 20 and the magnetic field B2 applied to the mass spectrometry unit 24. The magnetic shield 23 is made of a magnetic material such as an electromagnetic steel plate. The magnetic shield 23 includes a passage opening 23a through which the ion beam traveling from the extractor 22 toward the mass spectrometry unit 24 passes. The passage opening 23a may have the shape of a slit of which an opening width in the horizontal direction (x1 direction) is long and an opening width in the vertical direction (y direction) is short, like the front slit 20c. That is, the opening width of the passage opening 23a in the horizontal direction may be larger than the opening width of the passage opening 23a in the vertical direction.

The beam shaping unit 26 is provided downstream of the mass spectrometry unit 24. The beam shaping unit 26 is configured to shape the ion beam, which has passed through the mass spectrometry unit 24, into a desired cross-sectional shape and a desired convergence/divergence angle. The beam shaping unit 26 includes a lens device that adjusts at least one of the cross-sectional shape and the convergence/divergence angle of the ion beam. For example, the beam shaping unit 26 is configured to focus the ribbon-like ion beam, which spreads in the horizontal direction, to shape the ion beam into a spot-like ion beam.

The beam shaping unit 26 includes a plurality of lens devices, and includes, for example, three lens devices 26a, 26b, and 26c. The three lens devices 26a to 26c are configured as, for example, an electric field type three-stage quadrupole lens (also referred to as a triplet Q-lens). Since the plurality of the lens devices are used as the beam shaping unit 26 in combination, the beam shaping unit 26 can independently adjust the convergence or the divergence of the ion beam in each of the horizontal direction (x2 direction) and the vertical direction (y direction). The beam shaping unit 26 may include a magnetic field type lens device. The beam shaping unit 26 may include a lens device that shapes an ion beam using both an electric field and a magnetic field.

The beam scanner 28 is provided downstream of the beam shaping unit 26. The beam scanner 28 is configured to perform reciprocating scanning in a predetermined scanning direction with the ion beam to generate a scanning beam SB. The beam scanner 28 can also be referred to as a beam deflector that deflects the ion beam shaped by the beam shaping unit 26 in a predetermined scanning direction. The beam scanner 28 is configured such that a scanning direction is a direction different from the horizontal direction, and is configured such that, for example, the scanning direction is the vertical direction (y direction).

The beam scanner 28 includes a scanning electrode pair 28a, 28b that faces each other in the vertical direction (y direction). The scanning electrode pair 28a, 28b is connected to a variable voltage power supply (not shown). By periodically changing the voltage applied between the scanning electrode pair 28a, 28b, the electric field generated between the scanning electrode pair 28a, 28b is changed to deflect the ion beam at various angles. As a result, the entire scanning range in the vertical direction (y direction) is scanned with the ion beam. In FIG. 2, the scanning direction and the scanning range of the ion beam are illustrated by an arrow Y and a plurality of trajectories of the ion beam in the scanning range are shown by broken lines. The beam scanner 28 may be of a magnetic field type instead of an electric field type. The beam scanner 28 may include a magnet device for deflecting the ion beam.

The beam parallelizing unit 30 is provided downstream of the beam scanner 28. The beam parallelizing unit 30 is configured such that the traveling direction of the ion beam with which the reciprocating scanning has been performed by the beam scanner 28 is parallel to a direction of the beamline A. The beam parallelizing unit 30 includes a plurality of arc-shaped parallelizing lens electrodes 30a and 30b that are provided with passage slits for the ion beam in middle portions thereof in the horizontal direction (x2 direction). The parallelizing lens electrodes 30a and 30b are connected to a high-voltage power supply (not shown), and cause an electric field, which is generated by the application of a high voltage, to act on ion beam to make the traveling directions of the ion beam parallel to each other. The beam parallelizing unit 30 may be of a magnetic field type instead of an electric field type. The beam parallelizing unit 30 may include a magnet device for deflecting the ion beam.

The acceleration/deceleration unit 32 is provided downstream of the beam parallelizing unit 30. The acceleration/deceleration unit 32 is configured to accelerate or decelerate the scanning beam that is parallelized by the beam parallelizing unit 30. The acceleration/deceleration unit 32 is an electrostatic acceleration/deceleration device, and accelerates or decelerates the ion beam using a potential difference between a first potential applied to an upstream side of the acceleration/deceleration unit 32 and a second potential applied to a downstream side of the acceleration/deceleration unit 32.

The energy filter 34 is provided downstream of the acceleration/deceleration unit 32. The energy filter 34 is configured to analyze the energy of the ion beam and to allow ions having a desired energy to pass therethrough toward the implantation processing chamber 14. The energy filter 34 is an angle energy filter (AEF) that deflects the ion beam in the horizontal direction and selects ions having a desired energy depending on a deflection angle θ of the ion beam. The deflection angle θ is, for example, 10 degrees or more and 20 degrees or less, and is about 15 degrees. The energy filter 34 includes an AEF electrode pair 34a, 34b and an energy resolving aperture 34c.

The AEF electrode pair 34a, 34b is disposed to face each other in a direction orthogonal to the scanning direction. The AEF electrode pair 34a, 34b is disposed to face each other in the horizontal direction (x2 direction or x3 direction). The AEF electrode pair 34a, 34b is connected to a high-voltage power supply (not shown), and an electric field acts on the ion beam to deflect the ion beam. The AEF electrode pair 34a, 34b is a deflection device that deflects the scanning beam in the horizontal direction. The energy resolving aperture 34c is provided on a downstream side of the AEF electrode pair 34a, 34b.

The energy resolving aperture 34c has the shape of a slit of which an opening width in the vertical direction (y direction) is long and an opening width in the horizontal direction (x3 direction) is short. That is, the opening width of the energy resolving aperture 34c in the vertical direction is larger than the opening width of the energy resolving aperture 34c in the horizontal direction. The energy resolving aperture 34c allows the ion beam, which has a desired energy value or a desired energy range, to pass therethrough toward the workpieces W1 and W2, and blocks the other ion beams.

The energy filter 34 may be of a magnetic field type instead of an electric field type. The energy filter 34 may include a magnet device for deflection using a magnetic field. The energy filter 34 may use both an electric field and a magnetic field, and may include a pair of AEF electrodes for deflection using an electric field and a magnet device for deflection using a magnetic field.

In this way, the beam generator 12 supplies, to the implantation processing chamber 14, the ion beam to be irradiated onto the workpieces W1, W2. The beam generator 12 may be called a beamline unit. The beam generator 12 is configured to adjust operation parameters of various devices constituting the beam generator 12 to generate an ion beam for realizing desired implantation conditions.

The implantation processing chamber 14 includes a plasma shower device 36, a beam stopper 38, a first holding device 40, and a second holding device 42.

The plasma shower device 36 is positioned downstream of the energy filter 34. The plasma shower device 36 supplies low-energy electrons to the ion beam and the surfaces (processing target surfaces) of the workpieces W1 and W2 in accordance with the amount of the beam current of the ion beam to suppress charge-up that is caused by the accumulation of positive charges on the processing target surfaces occurring due to ion implantation. For example, the plasma shower device 36 includes a shower tube 36a through which the ion beam passes and a plasma generation unit 36b that supplies electrons into the shower tube 36a. The shower tube 36a has a shape in which an opening width in the vertical direction (y direction) is long and an opening width in the horizontal direction (x3 direction) is short.

The beam stopper 38 is provided at the most downstream of the beamline A, and is attached to, for example, a side wall of the implantation processing chamber 14. In a case where the workpieces W1 and W2 are not present in the beamline A, the ion beam is incident on the beam stopper 38. A plurality of tuning cups 38a, 38b, 38c, and 38d are provided on the beam stopper 38. The plurality of tuning cups 38a to 38d are Faraday cups that are configured to measure the beam current of the ion beam incident on the beam stopper 38. The plurality of tuning cups 38a to 38d are arranged, for example, at intervals in the vertical direction (y direction).

The first holding device 40 is configured to be capable of holding the first workpiece W1 to be subjected to the implantation processing. The first holding device 40 is configured to reciprocate the first workpiece W1, which is held by the first holding device 40, in a direction crossing the scanning beam. The first holding device 40 is configured to reciprocate the first workpiece W1 in the horizontal direction (x3 direction). The first holding device 40 is movable along guide rails 44 extending in the horizontal direction (x3 direction).

The first holding device 40 includes a first chuck mechanism 50, a first twist mechanism 52, a first vertical angle adjustment mechanism 54, a first horizontal angle adjustment mechanism 56, and a first reciprocating mechanism 58.

The first chuck mechanism 50 is configured to hold the first workpiece W1 in contact with a back surface of the first workpiece W1. The first chuck mechanism 50 includes, for example, an electrostatic chuck for holding the first workpiece W1. The first chuck mechanism 50 may include a temperature control mechanism for cooling or heating the first workpiece W1. The first chuck mechanism 50 includes a first lift mechanism for lifting the first workpiece W1 so that the first workpiece W1 is separated from the first chuck mechanism 50.

The first twist mechanism 52 supports the first chuck mechanism 50 such that the first chuck mechanism 50 is pivotable. The first twist mechanism 52 rotates the first chuck mechanism 50 about a rotation axis (also referred to as a twist axis), which extends in a normal direction of the processing target surface of the first workpiece W1 held by the first chuck mechanism 50, to adjust a twist angle φa1 of the first workpiece W1. For example, the first twist mechanism 52 adjusts the twist angle φa1 between an alignment mark provided on an outer peripheral portion of the first workpiece W1 and a reference position. Here, the alignment mark of the first workpiece W1 refers to, for example, a notch or an orientation flat that is provided on an outer peripheral portion of a wafer, and refers to a mark serving as a reference for an angular position in a crystal axis direction or a circumferential direction of the wafer.

The first vertical angle adjustment mechanism 54 supports the first twist mechanism 52 such that the first twist mechanism 52 is pivotable. The first vertical angle adjustment mechanism 54 rotates the first twist mechanism 52 about a rotation axis (also referred to as a transport tilt axis), which extends in the horizontal direction, to adjust an orientation of the first workpiece W1 in the vertical direction. The orientation of the first workpiece W1 in the vertical direction can be defined by a vertical pivot angle φb1 around the rotation axis extending in the horizontal direction.

The first horizontal angle adjustment mechanism 56 supports the first vertical angle adjustment mechanism 54 such that the first vertical angle adjustment mechanism 54 is pivotable. The first horizontal angle adjustment mechanism 56 rotates the first vertical angle adjustment mechanism 54 about a rotation axis (also referred to as an implantation tilt axis), which extends in the vertical direction, to adjust an orientation of the first workpiece W1 in the horizontal direction. The orientation of the first workpiece W1 in the horizontal direction can be defined by a horizontal pivot angle φc1 around the rotation axis extending in the vertical direction.

The first reciprocating mechanism 58 is configured to move the first horizontal angle adjustment mechanism 56 in the horizontal direction (x3 direction). The first reciprocating mechanism 58 moves the first horizontal angle adjustment mechanism 56 along the guide rails 44. For example, the first reciprocating mechanism 58 includes a first ball screw 58a that extends in the horizontal direction (x3 direction) along the guide rails 44. The first reciprocating mechanism 58 rotates the first ball screw 58a to linearly move the first horizontal angle adjustment mechanism 56 in the horizontal direction.

The second holding device 42 is configured to be capable of holding the second workpiece W2 to be subjected to the implantation processing. The second holding device 42 is configured to reciprocate the second workpiece W2, which is held by the second holding device 42, in a direction crossing the scanning beam. The second holding device 42 is configured to reciprocate the second workpiece W2 in the horizontal direction (x3 direction). The second holding device 42 is movable along the guide rails 44 extending in the horizontal direction (x3 direction).

The second holding device 42 can have the same configuration as the first holding device 40. The second holding device 42 is movable in the same direction as the first holding device 40. The second holding device 42 is movable along the guide rails 44 common to the first holding device 40. The second holding device 42 may be configured to be movable along guide rails different from the guide rails for the first holding device 40. That is, the implantation processing chamber 14 may be provided with first guide rails used to move the first holding device 40 and second guide rails used to move the second holding device 42. The second holding device 42 is movable simultaneously with the first holding device 40. The second holding device 42 is movable independently of the first holding device 40.

The second holding device 42 includes a second chuck mechanism 60, a second twist mechanism 62, a second vertical angle adjustment mechanism 64, a second horizontal angle adjustment mechanism 66, and a second reciprocating mechanism 68.

The second chuck mechanism 60 is configured to hold the second workpiece W2 in contact with a back surface of the second workpiece W2. The second chuck mechanism 60 includes, for example, an electrostatic chuck for holding the second workpiece W2. The second chuck mechanism 60 may include a temperature control mechanism for cooling or heating the second workpiece W2. The second chuck mechanism 60 includes a second lift mechanism for lifting the second workpiece W2 so that the second workpiece W2 is separated from the second chuck mechanism 60.

The second twist mechanism 62 supports the second chuck mechanism 60 such that the second chuck mechanism 60 is pivotable. The second twist mechanism 62 rotates the second chuck mechanism 60 about a rotation axis (also referred to as a twist axis), which extends in a normal direction of the processing target surface of the second workpiece W2 held by the second chuck mechanism 60, to adjust a twist angle φa2 of the second workpiece W2. For example, the second twist mechanism 62 adjusts the twist angle φa2 between an alignment mark provided on an outer peripheral portion of the second workpiece W2 and a reference position.

The second vertical angle adjustment mechanism 64 supports the second twist mechanism 62 such that the second twist mechanism 62 is pivotable. The second vertical angle adjustment mechanism 64 rotates the second twist mechanism 62 about a rotation axis (also referred to as a transport tilt axis), which extends in the horizontal direction, to adjust an orientation of the second workpiece W2 in the vertical direction. The orientation of the second workpiece W2 in the vertical direction can be defined by a vertical pivot angle φb2 around the rotation axis extending in the horizontal direction.

The second horizontal angle adjustment mechanism 66 supports the second vertical angle adjustment mechanism 64 such that the second vertical angle adjustment mechanism 64 is pivotable. The second horizontal angle adjustment mechanism 66 rotates the second vertical angle adjustment mechanism 64 about a rotation axis (also referred to as an implantation tilt axis), which extends in the vertical direction, to adjust an orientation of the second workpiece W2 in the horizontal direction. The orientation of the second workpiece W2 in the horizontal direction can be defined by a horizontal pivot angle φc2 around the rotation axis extending in the vertical direction.

The second reciprocating mechanism 68 is configured to move the second horizontal angle adjustment mechanism 66 in the horizontal direction (x3 direction). The second reciprocating mechanism 68 moves the second horizontal angle adjustment mechanism 66 along the guide rails 44. For example, the second reciprocating mechanism 68 includes a second ball screw 68a that extends in the horizontal direction (x3 direction) along the guide rails 44, and rotates the second ball screw 68a to linearly move the second horizontal angle adjustment mechanism 66 in the horizontal direction.

The transport device 16 includes a first transport device 70 and a second transport device 72. The first transport device 70 and the second transport device 72 are disposed away from the beamline A in the horizontal direction (x3 direction). In the example shown in FIG. 1, the first transport device 70 is disposed away from the beamline A in the −x3 direction, and the second transport device 72 is disposed away from the beamline A in the +x3 direction. For example, the first transport device 70 and the second transport device 72 are disposed such that the beam stopper 38 is positioned between the first transport device 70 and the second transport device 72.

The first transport device 70 is configured to transport the first workpiece W1, which is not yet subjected to the implantation processing, into the implantation processing chamber 14 and to transport the first workpiece W1, which has been subjected to the implantation processing, out of the implantation processing chamber 14. The first transport device 70 transports the first workpiece W1 into the first holding device 40 and transports the first workpiece W1 out of the first holding device 40. For example, the first transport device 70 includes a first transport robot (not shown) for transporting the first workpiece W1. The first transport device 70 transports the first workpiece W1 through a first transport port 74 provided in the side wall of the implantation processing chamber 14.

The second transport device 72 is configured to transport the second workpiece W2, which is not yet subjected to the implantation processing, into the implantation processing chamber 14 and to transport the second workpiece W2, which has been subjected to the implantation processing, out of the implantation processing chamber 14. The second transport device 72 transports the second workpiece W2 into the second holding device 42 and transports the second workpiece W2 out of the second holding device 42. For example, the second transport device 72 includes a second transport robot (not shown) for transporting the second workpiece W2. The second transport device 72 transports the second workpiece W2 through a second transport port 76 provided in the side wall of the implantation processing chamber 14.

The controller 18 controls an overall operation of the ion implanter 10. The controller 18 is realized by elements, such as a CPU and a memory of a computer, or a mechanical device in terms of hardware, and is realized by a computer program in terms of software. Various functions provided by the controller 18 can be realized by the cooperation of the hardware and the software.

The controller 18 includes a processor 18a such as a central processing unit (CPU) and a memory 18b such as a read-only memory (ROM) or a random-access memory (RAM). For example, the controller 18 causes the processor 18a to execute a program stored in the memory 18b to control the overall operation of the ion implanter 10 in accordance with the program. The processor 18a may execute a program stored in any storage device different from the memory 18b, may execute a program acquired from any recording medium by a reading device, or may execute a program acquired via a network. The memory 18b in which the program is stored may be a volatile memory such as a dynamic random access memory (DRAM), or may be a non-volatile memory such as an electrically erasable programmable read-only memory (EEPROM), a flash memory, a magnetoresistive memory, a resistive change memory, or a ferroelectric memory. A magnetic recording medium such as a non-volatile memory, a magnetic tape, and a magnetic disk, and an optical recording medium such as an optical disk are examples of a non-transitory and tangible computer-readable storage medium.

Various functions provided by the controller 18 may be realized by a single device including the processor 18a and the memory 18b, or may be realized by the cooperation of a plurality of devices, each of which includes the processor 18a and the memory 18b.

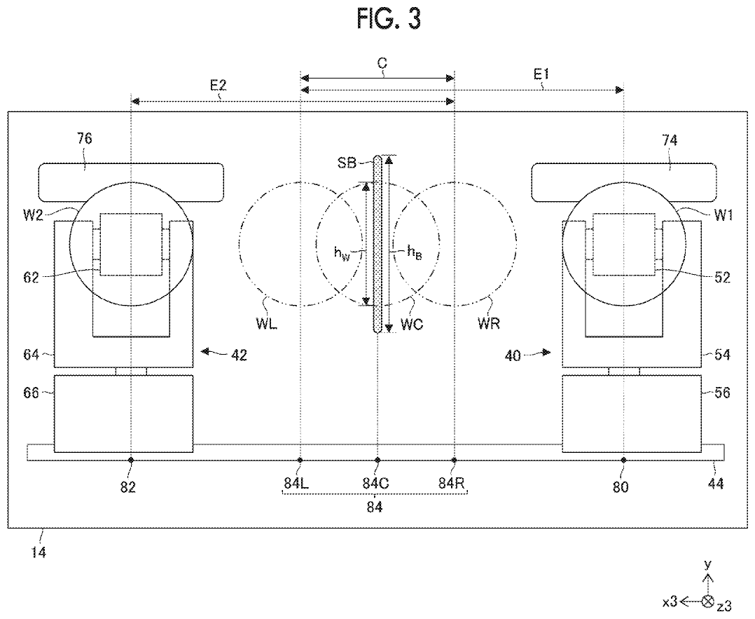

FIG. 3 is a front view showing a schematic configuration of the first holding device 40 and the second holding device 42, and shows a configuration as viewed in a beam traveling direction (z3 direction) in the implantation processing chamber 14. In FIG. 3, the first holding device 40 is disposed at a first transport position 80 and the second holding device 42 is disposed at a second transport position 82. The first transport position 80 is a position at which the first workpiece W1 is transported into the first holding device 40 or out of the first holding device 40 through the first transport port 74. The first transport position 80 corresponds to the position of the first transport port 74. The second transport position 82 is a position at which the second workpiece W2 is transported into the second holding device 42 or out of the second holding device 42 through the second transport port 76. The second transport position 82 corresponds to the position of the second transport port 76. The first transport position 80 and the second transport position 82 are away from an implantation position 84, at which the workpieces W1 and W2 are irradiated with the ion beam, in the horizontal direction (x3 direction).

The implantation position 84 is located in a middle portion of the implantation processing chamber 14 in the horizontal direction (x3 direction). The implantation position 84 is located between the first transport position 80 and the second transport position 82. The implantation position 84 includes an implantation center position 84C, an implantation left end position 84L, and an implantation right end position 84R. In FIG. 3, workpieces WC, WL, and WR positioned at the implantation center position 84C, the implantation left end position 84L, and the implantation right end position 84R, respectively, are shown by a two-dot chain line. The implantation center position 84C corresponds to a position where the scanning beam SB generated by the beam generator 12 is applied. The implantation left end position 84L is a position that is shifted to a left side (the +x3 direction in FIG. 3) from the implantation center position 84C, and is set such that the entire processing target surface of the workpiece WL disposed at the implantation left end position 84L does not overlap with the scanning beam SB. The implantation right end position 84R is a position that is shifted to a right side (the −x3 direction in FIG. 3) from the implantation center position 84C, and is set such that the entire processing target surface of the workpiece WR disposed at the implantation right end position 84R does not overlap with the scanning beam SB.

A size h_{B} of an irradiation range of the scanning beam SB in the vertical direction (y direction) is larger than a size h_{W} of the processing target surface of the workpieces W1, W2 in the vertical direction (y direction). The size h_{B} of the scanning beam SB in the vertical direction is, for example, 1.1 times or more and 3 times or less the size h_{W} of the surface of the workpieces W1, W2 in the vertical direction, and is preferably 1.2 times or more and 2 times or less.

The first holding device 40 reciprocates in the horizontal direction (x3 direction) at the implantation position 84, so that the entire processing target surface of the first workpiece W1 is irradiated with the scanning beam SB. The first holding device 40 reciprocates in a movement range C from the implantation left end position 84L to the implantation right end position 84R, so that the entire processing target surface of the first workpiece W1 is irradiated with the scanning beam SB. The first holding device 40 is moved to the first transport position 80, so that the first workpiece W1 can be transported in or out. The first holding device 40 is movable between the implantation position 84 and the first transport position 80. The first holding device 40 is movable over a first movable range E1 from the first transport position 80 to the implantation left end position 84L. The first holding device 40 is not movable to the second transport position 82.

The second holding device 42 reciprocates in the horizontal direction (x3 direction) at the implantation position 84, so that the entire processing target surface of the second workpiece W2 is irradiated with the scanning beam SB. The second holding device 42 reciprocates in the movement range C from the implantation left end position 84L to the implantation right end position 84R, so that the entire processing target surface of the second workpiece W2 is irradiated with the scanning beam SB. The second holding device 42 is moved to the second transport position 82, so that the second workpiece W2 can be transported in or out. The second holding device 42 is movable between the implantation position 84 and the second transport position 82. The second holding device 42 is movable over a second movable range E2 from the second transport position 82 to the implantation right end position 84R. The second holding device 42 is not movable to the first transport position 80.

A first implantation position at which the first workpiece W1 held by the first holding device 40 is irradiated with the ion beam is common to a second implantation position at which the second workpiece W2 held by the second holding device 42 is irradiated with the ion beam. That is, the first implantation position and the second implantation position coincide with the common implantation position 84. Further, a first movement range in which the first holding device 40 reciprocates the first workpiece W1 at the first implantation position is common to a second movement range in which the second holding device 42 reciprocates the second workpiece W2 at the second implantation position. That is, the first movement range and the second movement range coincide with the common movement range C. The first movement range and the second movement range overlap with each other as viewed in the beam traveling direction. The position of the first workpiece W1, which is held by the first holding device 40 at the first implantation position, in the vertical direction is common to the position of the second workpiece W2, which is held by the second holding device 42 at the second implantation position, in the vertical direction. The position of the first workpiece W1, which is held by the first holding device 40 at the first implantation position, in the beam traveling direction is common to the position of the second workpiece W2, which is held by the second holding device 42 at the second implantation position, in the beam traveling direction. Accordingly, the first holding device 40 and the second holding device 42 are configured to be capable of reciprocating the first workpiece W1 and the second workpiece W2 in the same manner with respect to the scanning beam SB. Therefore, the first workpiece W1 and the second workpiece W2 are irradiated with the scanning beam SB in a common implantation environment.

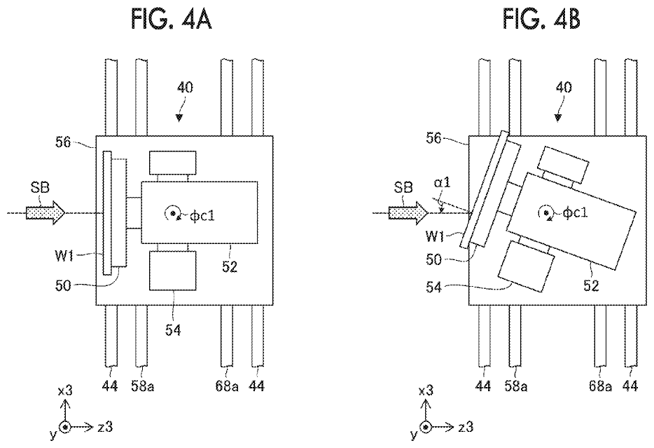

FIGS. 4A and 4B are top views schematically showing the horizontal orientation of the first workpiece W1 held by the first holding device 40. FIGS. 4A and 4B show a change in the horizontal orientation of the first workpiece W1 by the first horizontal angle adjustment mechanism 56. The same applies to the orientation of the second workpiece W2, which is held by the second holding device 42, in the horizontal direction.

FIGS. 4A and 4B show the orientation of the first workpiece W1 in an implantation step in which the first workpiece W1 is irradiated with the scanning beam SB. FIG. 4A shows a case where the processing target surface of the first workpiece W1 is perpendicular to the traveling direction (z3 direction) of the scanning beam SB. FIG. 4B shows a case where the processing target surface of the first workpiece W1 obliquely intersects with the traveling direction (z3 direction) of the scanning beam SB. In FIG. 4B, the processing target surface of the first workpiece W1 has a horizontal tilt angle α1 with respect to the traveling direction (z3 direction) of the scanning beam SB. The horizontal tilt angle α1 indicates a horizontal inclination of the incident direction of the scanning beam SB with respect to a normal to the processing target surface of the first workpiece W1. The first holding device 40 can adjust the horizontal tilt angle α1 of the first workpiece W1 by driving the first horizontal angle adjustment mechanism 56 to adjust the horizontal pivot angle φc1. The first holding device 40 is configured to be capable of adjusting the horizontal tilt angle α1 within, for example, a range of ±30 degrees or a range of ±60 degrees during ion implantation.

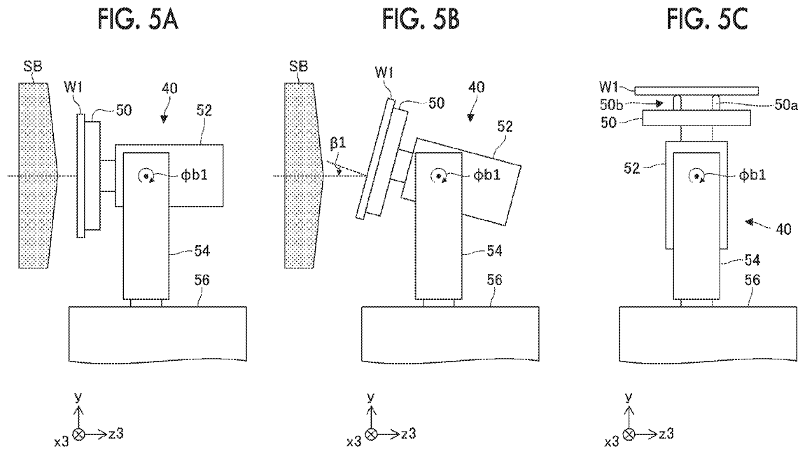

FIGS. 5A to 5C are side views schematically showing the orientation of the first workpiece W1, which is held by the first holding device 40, in the vertical direction. FIGS. 5A to 5C show a change in the orientation of the first workpiece W1, which is adjusted by the first vertical angle adjustment mechanism 54, in the vertical direction. The same applies to the orientation of the second workpiece W2, which is held by the second holding device 42, in the vertical direction.

FIG. 5A shows an example of the orientation of the first workpiece W1 in the implantation process in which the first workpiece W1 is irradiated with the scanning beam SB. In FIG. 5A, the first holding device 40 holds the first workpiece W1 such that the processing target surface of the first workpiece W1 is oriented in a direction perpendicular to the traveling direction (z3 direction) of the scanning beam SB. That is, the first holding device 40 holds the first workpiece W1 in an orientation in which the processing target surface of the first workpiece W1 is not along the horizontal direction. In the example shown in FIG. 5A, the first holding device 40 holds the first workpiece W1 in an orientation in which the processing target surface of the first workpiece W1 is along the vertical direction.

FIG. 5B shows another example of the orientation of the first workpiece W1 in the implantation process in which the first workpiece W1 is irradiated with the scanning beam SB. In FIG. 5B, the first holding device 40 holds the first workpiece W1 in an orientation in which the processing target surface of the first workpiece W1 is inclined with respect to the vertical direction. In FIG. 5B, the first holding device 40 holds the first workpiece W1 in an orientation in which the processing target surface of the first workpiece W1 is not along the horizontal direction. In FIG. 5B, the processing target surface of the first workpiece W1 has a vertical tilt angle β1 with respect to the traveling direction (z3 direction) of the scanning beam SB. The vertical tilt angle β1 indicates a vertical inclination of the incident direction of the scanning beam SB with respect to the normal to the processing target surface of the first workpiece W1. The first holding device 40 can adjust the vertical tilt angle β1 by driving the first vertical angle adjustment mechanism 54 to adjust the vertical pivot angle φb1. The first holding device 40 is configured to be capable of adjusting the vertical tilt angle β1 within, for example, a range of ±30 degrees or a range of ±60 degrees during ion implantation.

FIG. 5C shows the orientation of the first workpiece W1 in a transport process of transporting the first workpiece W1 into the first holding device 40 or out of the first holding device 40. In FIG. 5C, the first holding device 40 holds the first workpiece W1 in an orientation in which the processing target surface of the first workpiece W1 is along the horizontal direction. In FIG. 5C, the first holding device 40 lifts the first workpiece W1 using the first lift mechanism 50a so that the first workpiece W1 is separated from the first chuck mechanism 50. Accordingly, an arm of the first transport robot for transporting the first workpiece W1 in or out can be inserted into a gap 50b between the first chuck mechanism 50 and the first workpiece W1. It is not essential that the arm of the first transport robot is inserted into the gap 50b between the first chuck mechanism 50 and the first workpiece W1. The arm of the first transport robot may be configured to support the outer peripheral portion of the first workpiece W1 instead of the back surface of the first workpiece W1. In this case, the gap 50b may be very small.

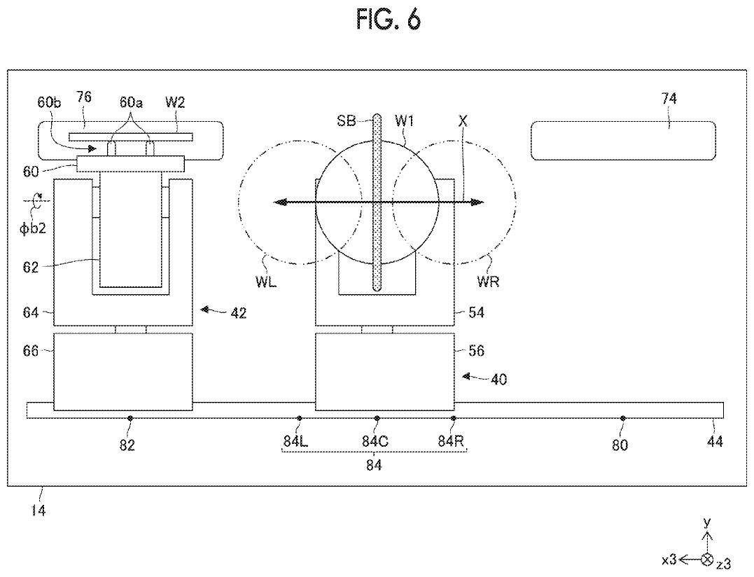

FIGS. 6 to 9 are front views showing an example of the operation of the first holding device 40 and the second holding device 42. FIG. 6 shows a situation in which a first implantation process is performed on the first workpiece W1. In FIG. 6, the first holding device 40 is disposed at the implantation position 84 and the second holding device 42 is disposed at the second transport position 82. The first holding device 40 reciprocates in the horizontal direction at the implantation position 84 as shown by an arrow X, for the implantation processing to be executed on the first workpiece W1. The second holding device 42 lifts the second workpiece W2 at the second transport position 82 using the second lift mechanism 60a, in order to transport the second workpiece W2, which has been subjected to the implantation processing, out through the second transport port 76. The second holding device 42 receives the second workpiece W2 at the second transport position 82 using the second lift mechanism 60a, in order to transport the second workpiece W2, which is not yet subjected to the implantation processing, in through the second transport port 76.

In FIG. 6, the first holding device 40 holds the first workpiece W1 such that the processing target surface of the first workpiece W1 is irradiated with the scanning beam SB. For example, the first holding device 40 holds the first workpiece W1 in an orientation in which the horizontal tilt angle α1 is 0 as shown in FIG. 4A. For example, the first holding device 40 holds the first workpiece W1 in an orientation in which the vertical tilt angle β1 is 0 as shown in FIG. 5A. The first holding device 40 may hold the first workpiece W1 in an orientation in which the horizontal tilt angle α1 is not 0 as shown in FIG. 4B. The first holding device 40 may hold the first workpiece W1 in an orientation in which the vertical tilt angle β1 is not 0 as shown in FIG. 5B. The first holding device 40 may hold the first workpiece W1 in an orientation in which both the horizontal tilt angle α1 and the vertical tilt angle β1 are not 0.

In FIG. 6, the second holding device 42 holds the second workpiece W2 such that the second workpiece W2 is oriented to be capable of being transported in or out through the second transport port 76. The second holding device 42 holds the second workpiece W2 in an orientation in which the processing target surface of the second workpiece W2 is along the horizontal direction as in FIG. 5C. The second holding device 42 lifts the second workpiece W2 using the second lift mechanism 60a to form a gap 60b between the second chuck mechanism 60 and the second workpiece W2. The second transport device 72 inserts an arm of the second transport robot into the gap 60b between the second chuck mechanism 60 and the second workpiece W2 to transport the second workpiece W2, which has been subjected to the implantation processing, out. In a case where the second workpiece W2 not yet subjected to the implantation processing is placed on the second lift mechanism 60a by the arm of the second transport robot, the second holding device 42 releases the lift of the second workpiece W2 and holds the second workpiece W2 in the second chuck mechanism 60. After holding the second workpiece W2 not yet subjected to the implantation processing, the second holding device 42 drives the second vertical angle adjustment mechanism 64 to change the vertical pivot angle φb2 and holds the second workpiece W2 in an orientation in which the processing target surface of the second workpiece W2 is not along the horizontal direction.

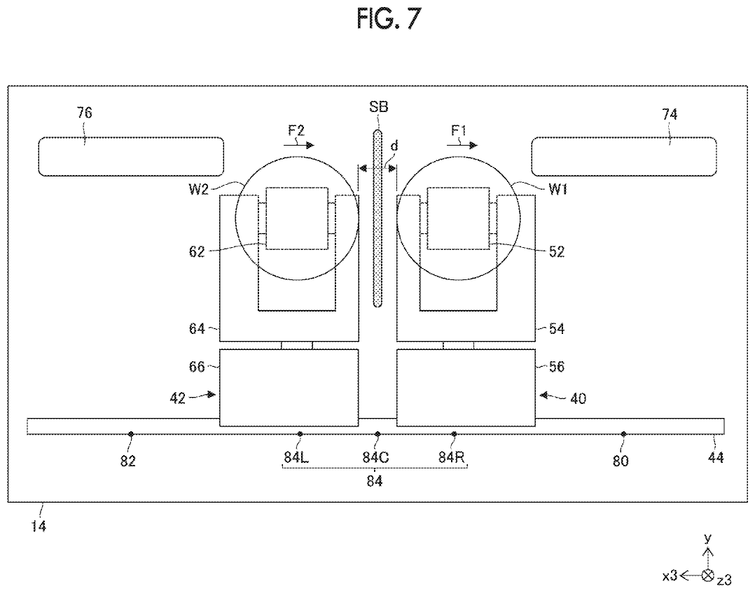

FIG. 7 shows a situation in which the first implantation process to be executed on the first workpiece W1 is switched to the second implantation process to be executed on the second workpiece W2. That is, FIG. 7 shows a situation in which the first implantation process to be executed on the first workpiece W1 ends and the second implantation process to be executed on the second workpiece W2 starts. In FIG. 7, the first holding device 40 is moved from the implantation position 84 toward the first transport position 80 as shown by an arrow F1, and the second holding device 42 is moved from the second transport position 82 toward the implantation position 84 as shown by an arrow F2. Since the first holding device 40 and the second holding device 42 are moved simultaneously in the same direction as shown in FIG. 7, a time required to switch from the first implantation process to the second implantation process can be shortened.

In FIG. 7, the first holding device 40 and the second holding device 42 can be moved such that a relative distance d between the first workpiece W1 held by the first holding device 40 and the second workpiece W2 held by the second holding device 42 is maintained. For example, in a case where the movement speeds of the first holding device 40 and the second holding device 42 are set to the same speed, the relative distance d can be maintained constant. The movement speeds of the first holding device 40 and the second holding device 42 may be adjusted to move the first holding device 40 and the second holding device 42 such that the relative distance d is maintained within a range from a predetermined upper limit to a predetermined lower limit. In this case, the movement speed of the first holding device 40 may be set to be higher or lower than the movement speed of the second holding device 42. In a case of ion implantation in which a uniform dose distribution is to be applied to the workpiece in the horizontal direction, it is preferable that the relative distance d is as short as possible. In a case of ion implantation in which a non-uniform dose distribution is to be applied to the workpiece in the horizontal direction, it is preferable that the relative distance d is larger than the size of the scanning beam SB in the horizontal direction (x3 direction).

In FIG. 7, the movement speed of the first holding device 40 that holds the first workpiece W1 on which the implantation process ends may be the maximum speed of the first holding device 40. In a case where the first holding device 40 is moved at the maximum speed, a time from the completion of the first implantation process on the first workpiece W1 to the transport-out of the first workpiece W1 can be shortened. As a result, productivity can be improved. On the other hand, the movement speed of the second holding device 42 that holds the second workpiece W2 on which the implantation process starts may be determined in accordance with implantation conditions of the second workpiece W2. In a case where the second holding device 42 is moved at a movement speed corresponding to the implantation conditions, the second workpiece W2 is moved to the implantation position 84 and then the second implantation process to be executed on the second workpiece W2 can start at the same movement speed. Accordingly, the start of the second implantation process can be accelerated, so that productivity can be improved.

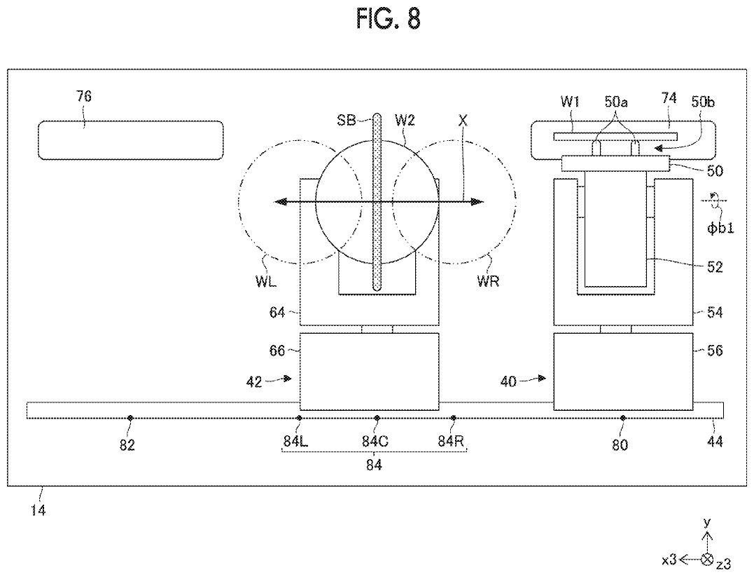

FIG. 8 shows a situation in which a second implantation process is performed on the second workpiece W2. In FIG. 8, the second holding device 42 is disposed at the implantation position 84 and the first holding device 40 is disposed at the first transport position 80. The second holding device 42 reciprocates in the horizontal direction at the implantation position 84 as shown by an arrow X, for the implantation processing to be executed on the second workpiece W2. The first holding device 40 lifts the first workpiece W1 at the first transport position 80 using the first lift mechanism 50a, in order to transport the first workpiece W1, which has been subjected to the implantation processing, out through the first transport port 74. The first holding device 40 receives the first workpiece W1 at the first transport position 80 using the first lift mechanism 50a, in order to transport the first workpiece W1, which is not yet subjected to the implantation processing, in through the first transport port 74.

In FIG. 8, the second holding device 42 holds the second workpiece W2 such that the processing target surface of the second workpiece W2 is irradiated with the scanning beam SB. For example, the second holding device 42 holds the second workpiece W2 in an orientation in which a horizontal tilt angle α2 is 0 as in FIG. 4A. For example, the second holding device 42 holds the second workpiece W2 in an orientation in which a vertical tilt angle β2 is 0 as in FIG. 5A. As in FIG. 4B, the second holding device 42 may hold the second workpiece W2 in an orientation in which the horizontal tilt angle α2 is not 0. The second holding device 42 may hold the second workpiece W2 in an orientation in which the vertical tilt angle β2 is not 0 as in FIG. 5B. The second holding device 42 may hold the second workpiece W2 in an orientation in which both the horizontal tilt angle α2 and the vertical tilt angle β2 are not 0.

In FIG. 8, the first holding device 40 holds the first workpiece W1 in an orientation that enables the first workpiece W1 to be transported in or out through the first transport port 74. The first holding device 40 holds the first workpiece W1 such that the processing target surface of the first workpiece W1 is oriented along the horizontal direction as shown in FIG. 5C. The first holding device 40 lifts the first workpiece W1 using the first lift mechanism 50a to form a gap 50b between the first chuck mechanism 50 and the first workpiece W1. The first transport device 70 inserts the arm of the first transport robot into the gap 50b between the first chuck mechanism 50 and the first workpiece W1 to transport the first workpiece W1, which has been subjected to the implantation processing, out. In a case where the first workpiece W1 not yet subjected to the implantation processing is placed on the first lift mechanism 50a by the arm of the first transport robot, the first holding device 40 releases the lift of the first workpiece W1 and holds the first workpiece W1 in the first chuck mechanism 50. After holding the first workpiece W1 not yet subjected to the implantation processing, the first holding device 40 drives the first vertical angle adjustment mechanism 54 to change the vertical pivot angle φb1 and holds the first workpiece W1 in an orientation in which the processing target surface of the first workpiece W1 is not along the horizontal direction.

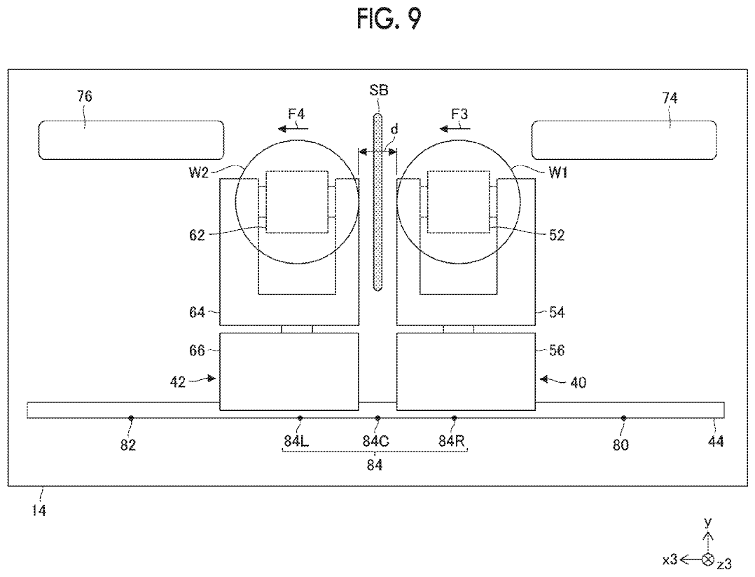

FIG. 9 shows a situation in which the second implantation process to be executed on the second workpiece W2 is switched to the first implantation process to be executed on the first workpiece W1. That is, FIG. 9 shows a situation in which the second implantation process to be executed on the second workpiece W2 ends and the first implantation process to be executed on the first workpiece W1 starts. In FIG. 9, the first holding device 40 is moved from the first transport position 80 toward the implantation position 84 as shown by an arrow F3, and the second holding device 42 is moved from the implantation position 84 toward the second transport position 82 as shown by an arrow F4. Since the first holding device 40 and the second holding device 42 are moved simultaneously in the same direction as shown in FIG. 9, a time required to switch from the second implantation process to the first implantation process can be shortened.

In FIG. 9, the first holding device 40 and the second holding device 42 can be moved such that a relative distance d between the first workpiece W1 held by the first holding device 40 and the second workpiece W2 held by the second holding device 42 is maintained. For example, in a case where the movement speeds of the first holding device 40 and the second holding device 42 are set to the same speed, the relative distance d can be maintained constant. The movement speeds of the first holding device 40 and the second holding device 42 may be adjusted to move the first holding device 40 and the second holding device 42 such that the relative distance d is maintained within a range from a predetermined upper limit to a predetermined lower limit. In this case, the movement speed of the first holding device 40 may be set to be higher or lower than the movement speed of the second holding device 42. It is preferable that the relative distance d is larger than the size of the scanning beam SB in the horizontal direction (x3 direction).

In FIG. 9, the movement speed of the second holding device 42 that holds the second workpiece W2 on which the implantation process ends may be the maximum speed of the second holding device 42. In a case where the second holding device 42 is moved at the maximum speed, a time from the completion of the second implantation process on the second workpiece W2 to the transport-out of the second workpiece W2 can be shortened. As a result, productivity can be improved. On the other hand, the movement speed of the first holding device 40 that holds the first workpiece W1 on which the implantation process starts may be determined in accordance with implantation conditions of the first workpiece W1. In a case where the first holding device 40 is moved at a movement speed corresponding to the implantation conditions, the first workpiece W1 is moved to the implantation position 84 and then the first implantation process to be executed on the first workpiece W1 can start at the same movement speed. Accordingly, the start of the first implantation process can be accelerated, so that productivity can be improved.

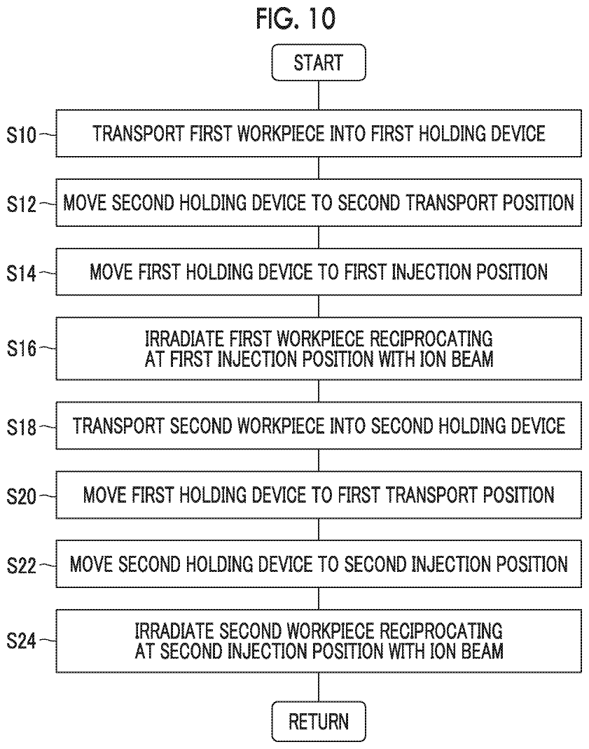

FIG. 10 is a flowchart illustrating a flow of an ion implantation method according to the embodiment. First, the first workpiece W1 not yet subjected to the implantation processing is transported into the first holding device 40 (S10). In S10, after the first workpiece W1, which has been subjected to the implantation processing and is held by the first holding device 40, is transported out, a first workpiece W1 not yet subjected to the implantation processing may be transported into the first holding device 40. Next, the second holding device 42 is moved to the second transport position 82 (S12), and the first holding device 40 is moved to the first implantation position (for example, the implantation position 84) (S14). S12 and S14 can be executed simultaneously, or can be executed such that the respective execution periods of S12 and S14 overlap with each other at least partially. Subsequently, the first holding device 40 is reciprocated at the first implantation position, so that the first workpiece W1, which reciprocates, is irradiated with the ion beam (S16).

Before, during, or after the execution of S16, a second workpiece W2 not yet subjected to the implantation processing is transported into the second holding device 42 (S18). In S18, after the second workpiece W2, which has been subjected to the implantation processing and is held by the second holding device 42, is transported out, a second workpiece W2 not yet subjected to the implantation processing may be transported into the second holding device 42. Next, the first holding device 40 is moved to the first transport position 80 (S20), and the second holding device 42 is moved to the second implantation position (for example, the implantation position 84) (S22). S20 and S22 can be executed simultaneously, or can be executed such that the respective execution periods of S20 and S22 overlap with each other at least partially. Subsequently, the second holding device 42 is reciprocated at the second implantation position, so that the second workpiece W2, which reciprocates, is irradiated with the ion beam (S24).

The flow shown in FIG. 10 can be repeatedly executed. For example, the processing of S10 to be executed after the repetition can be executed before, during, or after the execution of S24. Before, during, or after the execution of S24, the first workpiece W1, which has been subjected to the implantation processing and is held by the first holding device 40, can be transported out, and the first workpiece W1 not yet subjected to the implantation processing can be transported into the first holding device 40. In a case where the flow shown in FIG. 10 is repeated, the first implantation process to be executed on the first workpiece W1 held by the first holding device 40 and the second implantation process to be executed on the second workpiece W2 held by the second holding device 42 can be alternately repeated. The flow shown in FIG. 10 can be repeatedly executed until implantation processes for a plurality of workpieces to be continuously processed are completed.

According to the present embodiment, the plurality of holding devices are provided in the implantation processing chamber 14. Accordingly, the implantation processes and the transport processes for workpieces can be executed in parallel. For example, the transport process of transporting the second workpiece W2 can be executed by the second holding device 42 simultaneously with the first implantation process to be executed on the first workpiece W1 held by the first holding device 40. Further, the transport process of transporting the first workpiece W1 can be executed by the first holding device 40 simultaneously with the second implantation process to be executed on the second workpiece W2 held by the second holding device 42. As a result, as compared to a case where the implantation process and the transport process are alternately executed using a single holding device, a time required to continuously process a plurality of workpieces can be shortened and productivity can be improved.

According to the present embodiment, the plurality of holding devices are configured to reciprocate in the horizontal direction. Accordingly, the complexity of the configuration of the implantation processing chamber 14 and the transport device 16 can be suppressed as compared to a configuration in which the plurality of holding devices reciprocate in the vertical direction. Further, since the plurality of holding devices are configured to reciprocate in the horizontal direction, the sizes of the implantation processing chamber 14 and the transport device 16 in the vertical direction can be reduced. As a result, the ion implanter 10 having an external size within a height limit range on a floor of a general semiconductor processing factory can be provided.

According to the present embodiment, the plurality of holding devices are configured to move along the common guide rails 44. Accordingly, the reciprocation of the plurality of respective holding devices at the implantation position can be made common. Therefore, it is possible to prevent a difference in the implantation environment from occurring due to the use of the plurality of holding devices. As a result, it is possible to improve the productivity of the implantation processing to be executed on the plurality of workpieces while suppressing a variation in the implantation processing to be executed on the plurality of workpieces.

According to the present embodiment, reciprocating scanning is performed in the vertical direction with the ion beam and the workpiece is reciprocated in the horizontal direction. Accordingly, the entire processing target surface of the workpiece can be efficiently irradiated with the scanning beam. Further, since the ion beam is deflected in the horizontal direction in the mass spectrometry unit 24 and the energy filter 34, the beamline A that travels along the horizontal plane can be formed. Accordingly, the size of the beam generator 12 in the vertical direction can be reduced.

According to the present embodiment, the front slit 20c of the ion source 20 is formed in the shape of a slit long in the horizontal direction. Accordingly, the ion beam spreading in the horizontal direction can be generated through the extractor 22. As a result, it is easy to generate an ion beam having a large beam current as compared to a case where a spot-like ion beam is extracted from the ion source 20. Further, since the size of the ion beam, which is extracted from the ion source 20, in the vertical direction is small, an interval between magnetic poles, which face each other and through which the ion beam passes, of the mass spectrometry magnet device 24a can be made small. As a result, the size of the mass spectrometry magnet device 24a can be reduced. For example, as compared to a comparative example in which a front slit of the ion source is formed in the shape of a slit narrow in the horizontal direction and long in the vertical direction, it is possible to generate an ion beam having a large beam current while reducing the size of the mass spectrometry magnet device 24a.

According to the present embodiment, the ion beam spreading in the horizontal direction is formed into a spot shape by the beam shaping unit 26. Accordingly, a spot beam suitable for beam scanning in the vertical direction, which is performed by the beam scanner 28, can be formed. Scanning is performed in the vertical direction with the spot beam by the beam scanner 28, so that ions can be implanted into a workpiece having a large size in the vertical direction. According to the present embodiment, a workpiece having a large size in the vertical direction can be irradiated with a scanning beam having a larger beam current. Accordingly, the productivity of the implantation processing can be improved.

In the present embodiment, a direction in which the magnetic field B1 is applied to the ion source 20 and a direction in which the magnetic field B2 is applied to the mass spectrometry unit 24 are perpendicular to each other. Accordingly, there is a high possibility that the quality of the beam and the control of the magnetic field may be adversely affected by interference between both the magnetic field B1 and the magnetic field B2. On the other hand, in the case of the comparative example in which a direction in which a magnetic field is applied to the ion source is the vertical direction, the direction in which a magnetic field is applied to the ion source and a direction in which a magnetic field is applied to the mass spectrometry unit are parallel to each other. Therefore, even if both the magnetic fields interfere with each other to some extent, there is no major problem. According to the present embodiment, the magnetic shield 23 is provided between the extractor 22 and the mass spectrometry unit 24. Accordingly, magnetic field interference between the magnetic field B1 that is parallel to the horizontal direction and applied to the ion source 20 and the magnetic field B2 that is parallel to the vertical direction and applied to the mass spectrometry unit 24 can be suppressed. Therefore, it is possible to achieve both high plasma generation efficiency of the ion source 20 and high mass spectrometry accuracy of the mass spectrometry unit 24.

The present embodiment can be applied to the ion implantation processing to be executed on a workpiece having a large size in the vertical direction. An example of the workpiece having a large size in the vertical direction is a large substrate that is used to manufacture a flat panel display (FPD). The sizes of such a large substrate in the vertical direction and the horizontal direction are, for example, 1 m×2 m or more. It is not realistic to reciprocate such a large workpiece in the vertical direction. According to the present embodiment, the workpiece is reciprocated in the horizontal direction. Therefore, it is easy to reciprocate a large substrate as compared to a case where the workpiece is reciprocated in the vertical direction. A large substrate, which reciprocates in the horizontal direction, is irradiated with a scanning beam that is scanned in the vertical direction, so that ion implantation processing can be executed on the large substrate.

In a case where a workpiece is a large substrate for an FPD, the ion implanter 10 may not include at least one of the beam parallelizing unit 30, the acceleration/deceleration unit 32, and the energy filter 34. In a case where a workpiece is a large substrate for an FPD, the implantation processing chamber 14 may transport the workpiece into the implantation processing chamber 14 and transport the workpiece out of the implantation processing chamber 14 by moving the workpiece in a horizontal direction. For example, a large substrate not yet subjected to the implantation processing may be transported into the implantation processing chamber 14 from the right side (or left side) of the implantation processing chamber 14 and may be moved in the leftward direction (or rightward direction) in the implantation processing chamber 14 and be subjected to the ion implantation processing, and the large substrate having been subjected to the implantation processing may be transported out of the implantation processing chamber 14 from the left side (or right side) of the implantation processing chamber 14. Accordingly, the ion implanter 10 may continuously process a large substrate in an in-line manner.

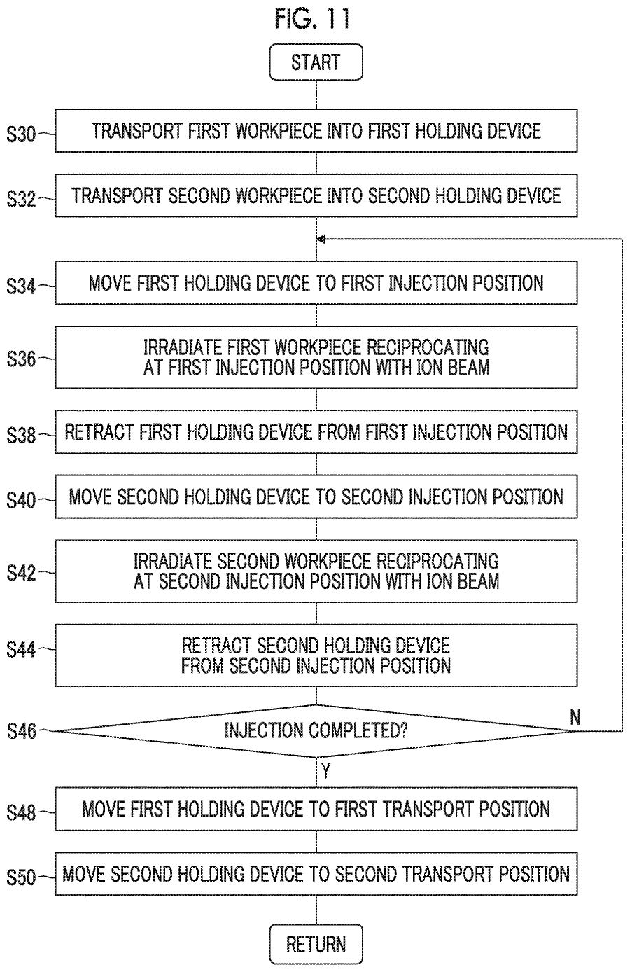

FIG. 11 is a flowchart showing a flow of an ion implantation method according to a modification example. In the flow shown in FIG. 11, a first implantation process to be executed on the first workpiece W1 and a second implantation process to be executed on the second workpiece W2 are executed in parallel.

First, the first workpiece W1 not yet subjected to the implantation processing is transported into the first holding device 40 (S30). In S30, after the first workpiece W1, which has been subjected to the implantation processing and is held by the first holding device 40, is transported out, a first workpiece W1 not yet subjected to the implantation processing may be transported into the first holding device 40. Further, a second workpiece W2 not yet subjected to the implantation processing is transported into the second holding device 42 (S32). In S32, after the second workpiece W2, which has been subjected to the implantation processing and is held by the second holding device 42, is transported out, a second workpiece W2 not yet subjected to the implantation processing may be transported into the second holding device 42. An order of the processes S30 and S32 is not limited, and S32 may start after the start of S30 or S30 may start after the start of S32. The processes S30 and S32 may be executed simultaneously.

Subsequently, the first holding device 40 is moved to the first implantation position (for example, the implantation position 84) (S34). The first holding device 40 is reciprocated at the first implantation position, so that the first workpiece W1, which reciprocates, is irradiated with the ion beam (S36). The number of reciprocations of the first workpiece W1 in S36 is not particularly limited, and may be, for example, only one. Then, the first holding device 40 is retreated from the first implantation position (S38), and the second holding device 42 is moved to the second implantation position (for example, the implantation position 84) (S40). A first retreat position to which the first holding device 40 is retreated is located between, for example, the first transport position 80 and the first implantation position. The first retreat position to which the first holding device 40 is retreated may be the same as the first transport position 80.

Subsequently, the second holding device 42 is reciprocated at the second implantation position, so that the second workpiece W2, which reciprocates, is irradiated with the ion beam (S42). The number of reciprocations of the second workpiece W2 in S42 is not particularly limited, and may be, for example, only one. Then, the second holding device 42 is retreated from the second implantation position (S44). A second retreat position to which the second holding device 42 is retreated is located between, for example, the second transport position 82 and the second implantation position. The second retreat position to which the second holding device 42 is retreated may be the same as the second transport position 82.

In a case where the implantation processing to be executed on the first workpiece W1 and the second workpiece W2 is not completed (N in S46), the processes S34 to S44 are repeated until the implantation processing is completed. For example, in a case where the number of reciprocations of the workpiece required for the completion of the implantation processing of the first workpiece W1 and the second workpiece W2 is three (that is, three reciprocations), the processes S34 to S44 are repeated three times. In this case, a process in which the first workpiece W1 reciprocates once and is irradiated with the ion beam and a process in which the second workpiece W2 reciprocates once and is irradiated with the ion beam are alternately executed three times each. In this case, a relative distance d between the first workpiece W1 and the second workpiece W2 can be set to be as small as possible so that S38 and S40 can be executed simultaneously, and a relative distance d between the first workpiece W1 and the second workpiece W2 can be set to be as small as possible so that S44 and S34 can be executed simultaneously. That is, a state in which the relative distance d between the first workpiece W1 and the second workpiece W2 is set to be as small as possible can be maintained so that the first workpiece W1 and the second workpiece W2 can be reciprocated in the same direction in synchronization with each other. Accordingly, the utilization efficiency of the ion beam can be improved.

In a case where the implantation processing is completed in S46 (Y in S46), the first holding device 40 is moved to the first transport position 80 (S48) and the second holding device 42 is moved to the second transport position 82 (S50). An order of the processes S48 and S50 is not limited, and S50 may start after the start of S48 or S48 may start after the start of S50. The processes S48 and S50 may be executed simultaneously. Further, since the first holding device 40 is already disposed at the first transport position 80 in the process S38 in a case where the first retreat position is the first transport position 80, the process S48 may be omitted. Similarly, since the second holding device 42 is already disposed at the second transport position 82 in the process S44 in a case where the second retreat position is the second transport position 82, the process S50 may be omitted.

The flow shown in FIG. 11 can be repeatedly executed until implantation processes for a plurality of workpieces to be continuously processed are completed. According to the flow shown in FIG. 11, a first transport process in which the first workpiece W1 is transported into and out of the first holding device 40 and a second transport process in which the second workpiece W2 is transported into and out of the second holding device 42 can be executed simultaneously. Therefore, productivity can be improved. It is preferable that the flow shown in FIG. 11 is applied in a case where an implantation time taken to irradiate a workpiece with an ion beam is sufficiently short (for example, half or less) as compared to a transport time taken to transport the workpiece in and out. Further, it is also preferable that the flow shown in FIG. 11 is applied in a case where an implantation time taken to irradiate a workpiece with an ion beam is sufficiently long (for example, twice or more) as compared to a transport time taken to transport the workpiece in and out. The flow shown in FIG. 11 can also be applied in a case where an implantation time taken to irradiate a workpiece with an ion beam is substantially the same as a transport time taken to transport the workpiece in and out. However, in this case, productivity in the flow shown in FIG. 10 may be higher than that in the flow shown in FIG. 11.

A case where the beam generator 12 generates a scanning beam using the beam scanner 28 and the beam parallelizing unit 30 has been described in the above-described embodiment. In another embodiment, the beam generator may generate a ribbon beam. The beam generator may include a ribbon beam generation unit instead of the beam scanner 28. The ribbon beam generation unit causes a spot-like ion beam to diverge in the vertical direction to generate a ribbon beam. The ribbon beam generation unit may be formed of an electric field type or a magnetic field type beam divergence unit.

A case where the ion beam extracted from the ion source 20 is a ribbon-like beam spreading in the horizontal direction has been described in the above-described embodiment. In another embodiment, the ion beam extracted from the ion source may be a ribbon beam spreading in the vertical direction. In this case, the front slit of the ion source has the shape of a slit of which an opening width in the vertical direction is long and an opening width in the horizontal direction is short. Similarly, the extraction electrodes of the extractor have the shape of a slit of which an opening width in the vertical direction is long and an opening width in the horizontal direction is short. In this case, the mass spectrometry unit is configured to deflect the ribbon beam, which spreads in the vertical direction, in the horizontal direction. In this case, the beam generator may not include the beam scanner 28 and the beam parallelizing unit 30. In this case, the ion source and the extractor can be referred to as a ribbon beam generation unit for generating a ribbon beam that spreads in the vertical direction.

In another embodiment described above, the size of an irradiation range, which is irradiated with a ribbon beam spreading in the vertical direction, in the vertical direction is larger than the size of the workpiece in the vertical direction. Therefore, the beam generator that generates a ribbon beam is configured to irradiate an irradiation range, of which the size in the vertical direction is larger than the size of the processing target surface of a workpiece, with an ion beam. In the above-described embodiment, the beam generator 12 that generates a scanning beam is configured to irradiate an irradiation range, of which the size in the vertical direction is larger than the size of the processing target surface of a workpiece, with the ion beam.

In the above-described embodiment, a case has been described in which a plurality of holding devices 40, 42 are provided in the implantation processing chamber 14. In another embodiment, only a single holding device may be provided in the implantation processing chamber 14. The single holding device may have the same configuration as any one of the first holding device 40 and the second holding device 42 described above.

A case where the scanning direction of the scanning beam SB is the vertical direction has been described in the above-described embodiment. In another embodiment, the scanning direction of the scanning beam SB may be inclined with respect to the vertical direction. In this case, the beam scanner 28, the beam parallelizing unit 30, the acceleration/deceleration unit 32, and the energy filter 34 are disposed at positions rotated about the beamline A extending in the z2 direction (for example, at positions downstream of the mass spectrometry unit 24 and upstream of the beam scanner 28) as a rotation axis (that is, in an inclined direction). Only the beam scanner 28 and the beam parallelizing unit 30 may be disposed to be rotated, and at least one of the acceleration/deceleration unit 32 and the energy filter 34 may be disposed not to be rotated. In this case, it is preferable that the scanning direction of the scanning beam SB is within 45 degrees from the vertical direction.

A case where the first holding device 40 and the second holding device 42 are moved in the horizontal direction has been described in the above-described embodiment. In another embodiment, the moving direction of the first holding device 40 and the second holding device 42 may not be the horizontal direction and may be inclined with respect to the horizontal direction. The moving direction of the first holding device 40 and the second holding device 42 may be a direction different from the horizontal direction, and may be any direction crossing the scanning beam.

Aspects of the present disclosure are as follows.
(Item 1) An ion implanter including: an ion source that generates ions; an extractor that extracts the ions from the ion source to generate an ion beam; a beam scanner that is configured to perform reciprocating scanning in a scanning direction different from a horizontal direction with the ion beam to generate a scanning beam; and a holding device that is configured to hold a workpiece and to reciprocate the workpiece, which is held by the holding device, in a direction crossing the scanning beam.
(Item 2) The ion implanter according to Item 1, in which the holding device is configured to reciprocate the workpiece, which is held by the holding device, in the horizontal direction.
(Item 3) The ion implanter according to Item 1 or 2, in which the scanning direction is a direction within 45 degrees from a vertical direction.
(Item 4) The ion implanter according to Item 1 or 2, in which the scanning direction is a vertical direction.
(Item 5) The ion implanter according to any one of Items 1 to 4, in which the ion source includes a front slit through which the ions extracted by the extractor pass, and an opening width of the front slit in the horizontal direction is larger than an opening width of the front slit in the vertical direction.
(Item 6) The ion implanter according to Item 5, in which the ion source includes an arc chamber including an internal space and including a front slit for extracting ions from plasma generated in the internal space, and a magnet device that applies a magnetic field in the horizontal direction to the internal space.
(Item 7) The ion implanter according to Item 5 or 6, in which the extractor includes extraction electrodes including extraction openings through which the ion beam passes, and an opening width of the extraction opening in the horizontal direction is larger than an opening width of the extraction opening in the vertical direction.
(Item 8) The ion implanter according to any one of Items 1 to 7, further including a mass spectrometry unit that is provided between the extractor and the beam scanner and deflects the ion beam in the horizontal direction.
(Item 9) The ion implanter according to Item 8, in which the mass spectrometry unit includes a magnet device that applies a magnetic field, which is parallel to a vertical direction, to the ion beam.
(Item 10) The ion implanter according to Item 8 or 9, further including a magnetic shield that is provided between the extractor and the mass spectrometry unit and includes a passage opening through which the ion beam passes.
(Item 11) The ion implanter according to any one of Items 8 to 10, further including a beam shaping unit that is provided between the mass spectrometry unit and the beam scanner and includes at least one lens device for adjusting at least one of a cross-sectional shape and a convergence/divergence angle of the ion beam.
(Item 12) The ion implanter according to any one of Items 1 to 11, further including a beam parallelizing unit that is provided on a downstream side of the beam scanner and parallelizes the scanning beam.
(Item 13) The ion implanter according to any one of Items 1 to 12, further including an energy filter that includes a deflector deflecting the scanning beam in the horizontal direction and an energy resolving aperture provided on a downstream side of the deflector.
(Item 14) The ion implanter according to Item 13, in which the deflector includes a pair of electrodes that face each other with the scanning beam interposed therebetween, and a power supply that applies a DC voltage to the pair of electrodes.
(Item 15) The ion implanter according to Item 14, in which the pair of electrodes of the deflector is disposed to face each other in the horizontal direction.
(Item 16) The ion implanter according to Item 14, in which the pair of electrodes of the deflector is disposed to face each other in a direction perpendicular to the scanning direction.
(Item 17) An ion implantation method including: generating ions using an ion source, generating an ion beam by extracting the ions from the ion source, performing reciprocating scanning in a scanning direction different from a horizontal direction with the ion beam to generate a scanning beam; and performing reciprocating scanning of the workpiece in a direction crossing the scanning beam.

Aspects of the present disclosure are as follows.
(Item 18) An ion implanter including: a beam generator configured to generate an ion beam irradiated onto a workpiece and to irradiate the ion beam over the irradiation range, the irradiation range having a size in a vertical direction larger than a size of a processing target surface of the workpiece; a first holding device configured to hold a first workpiece and configured to reciprocate the first workpiece in a horizontal direction such that the first workpiece held by the first holding device crosses the irradiation range; and a second holding device configured to hold a second workpiece and configured to reciprocate the second workpiece in the horizontal direction such that the second workpiece held by the second holding device crosses the irradiation range.
(Item 19) The ion implanter according to Item 18, in which the first holding device is configured to be movable between a first implantation position at which the first workpiece is irradiated with the ion beam and a first transport position at which the first workpiece is transported into the first holding device or out of the first holding device, and the second holding device is configured to be movable between a second implantation position at which the second workpiece is irradiated with the ion beam and a second transport position at which the second workpiece is transported into the second holding device or out of the second holding device.
(Item 20) The ion implanter according to Item 19, in which the first implantation position and the second implantation position are located between the first transport position and the second transport position.
(Item 21) The ion implanter according to Item 19 or 20, in which a first movement range in which the first holding device reciprocates the first workpiece at the first implantation position and a second movement range in which the second holding device reciprocates the second workpiece at the second implantation position overlap with each other as viewed in a beam traveling direction.
(Item 22) The ion implanter according to Item 21, in which the first movement range is common to the second movement range.
(Item 23) The ion implanter according to any one of Items 19 to 22, in which a position of the first workpiece, which is held by the first holding device at the first implantation position, in the vertical direction is common to a position of the second workpiece, which is held by the second holding device at the second implantation position, in the vertical direction.
(Item 24) The ion implanter according to any one of Items 19 to 23, in which a position of the first workpiece, which is held by the first holding device at the first implantation position, in a beam traveling direction is common to a position of the second workpiece, which is held by the second holding device at the second implantation position, in the beam traveling direction.
(Item 25) The ion implanter according to any one of Items 19 to 24, in which the first holding device is configured to be not movable to the second transport position, and the second holding device is configured to be not movable to the first transport position.
(Item 26) The ion implanter according to any one of Items 18 to 25, in which the first holding device and the second holding device are movable in the same direction.
(Item 27) The ion implanter according to any one of Items 18 to 26, in which the first holding device and the second holding device are simultaneously movable in the same direction while maintaining a relative distance between the first workpiece held by the first holding device and the second workpiece held by the second holding device.
(Item 28) The ion implanter according to any one of Items 18 to 27, in which the first holding device and the second holding device are movable along a common guide rail.
(Item 29) The ion implanter according to any one of Items 18 to 28, in which the first holding device includes a first vertical angle adjustment mechanism that adjusts an orientation of the first workpiece in the vertical direction and a first horizontal angle adjustment mechanism that adjusts an orientation of the first workpiece in the horizontal direction, and the second holding device includes a second vertical angle adjustment mechanism that adjusts an orientation of the second workpiece in the vertical direction and a second horizontal angle adjustment mechanism that adjusts an orientation of the second workpiece in the horizontal direction.
(Item 30) The ion implanter according to any one of Items 18 to 28, in which the first holding device includes a first vertical angle adjustment mechanism that is rotated about a rotation axis extending in the horizontal direction to adjust an orientation of the first workpiece, and a first horizontal angle adjustment mechanism that is rotated about a rotation axis extending in the vertical direction to adjust an orientation of the first workpiece, and the second holding device includes a second vertical angle adjustment mechanism that is rotated about a rotation axis extending in the horizontal direction to adjust an orientation of the second workpiece, and a second horizontal angle adjustment mechanism that is rotated about a rotation axis in the vertical direction to adjust an orientation of the second workpiece.
(Item 31) The ion implanter according to any one of Items 18 to 28, in which the first holding device includes a first vertical angle adjustment mechanism that adjusts an orientation of the first workpiece, and the first vertical angle adjustment mechanism adjusts the orientation of the first workpiece such that the processing target surface of the first workpiece is oriented along the horizontal direction in a case where the first workpiece is to be transported in or out, and adjusts the orientation of the first workpiece such that the processing target surface of the first workpiece is oriented not along the horizontal direction in a case where the first workpiece is to be irradiated with the ion beam, and the second holding device includes a second vertical angle adjustment mechanism that adjusts an orientation of the second workpiece, and the second vertical angle adjustment mechanism adjusts the orientation of the second workpiece such that the processing target surface of the second workpiece is oriented along the horizontal direction in a case where the second workpiece is to be transported in or out, and adjusts the orientation of the second workpiece such that the processing target surface of the second workpiece is oriented not along the horizontal direction in a case where the second workpiece is to be irradiated with the ion beam.
(Item 32) The ion implanter according to any one of Items 18 to 31, in which the first holding device includes a first horizontal angle adjustment mechanism that adjusts an orientation of the first workpiece in the horizontal direction and a first twist mechanism that adjusts a twist angle of the first workpiece, and the second holding device includes a second horizontal angle adjustment mechanism that adjusts an orientation of the second workpiece in the horizontal direction and a second twist mechanism that adjusts a twist angle of the second workpiece.
(Item 33) The ion implanter according to any one of Items 18 to 32, in which the beam generator includes a beam scanner that performs reciprocating scanning with the ion beam over the irradiation range.
(Item 34) The ion implanter according to any one of Items 18 to 32, in which the beam generator includes a ribbon beam generation unit that generates a ribbon beam having a beam size corresponding to a size of the irradiation range.
(Item 35) An ion implantation method including: generating an ion beam with which a workpiece is irradiated; irradiating the ion beam over the irradiation range, the irradiation range having a size in a vertical direction larger than a size of a processing target surface of the workpiece; causing the first workpiece to be held by the first holding device; using the first holding device to reciprocate the first workpiece in a horizontal direction such that the first workpiece crosses the irradiation range; causing the second workpiece to be held by the second holding device; and using the second holding device to reciprocate the second workpiece in the horizontal direction such that the second workpiece crosses the irradiation range.

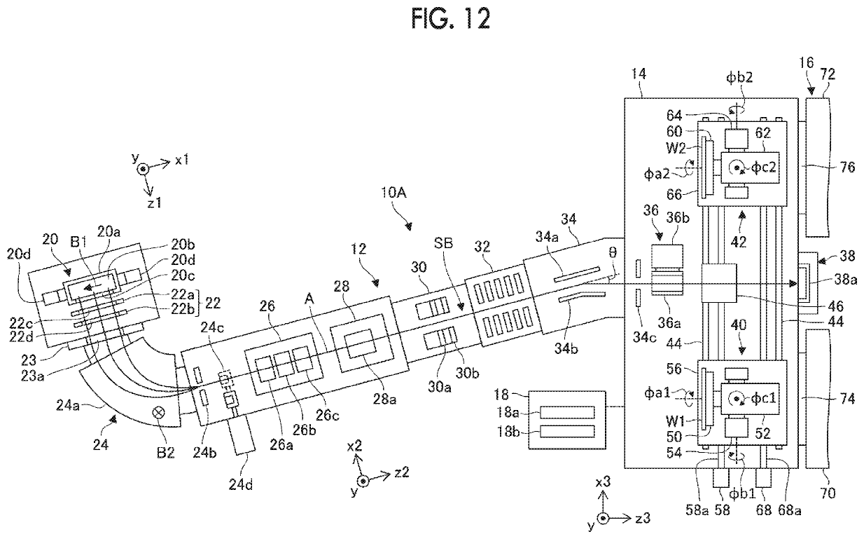

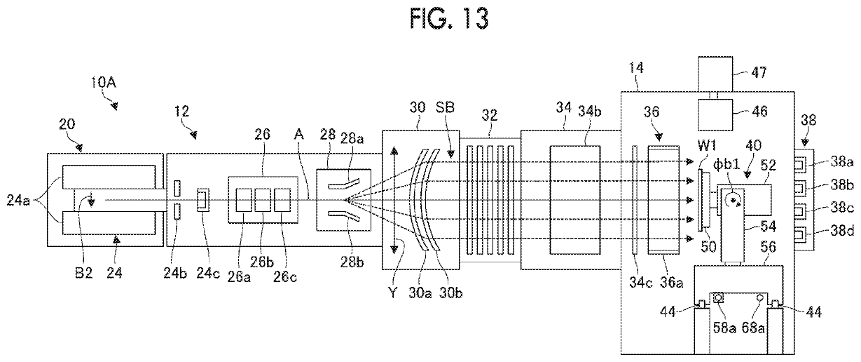

FIG. 12 is a top view showing a schematic configuration of an ion implanter 10A according to another embodiment. FIG. 13 is a side view showing a schematic configuration of the ion implanter 10A according to another embodiment. The ion implanter 10A shown in FIGS. 12 and 13 is different from the ion implanter 10 shown in FIGS. 1 and 2 in that the ion implanter 10A further includes a beam profiler 46 provided in the implantation processing chamber 14. Hereinafter, the ion implanter 10A will be described with the differences from the above-described embodiment as the main point, and the common points will be appropriately omitted from the description.

The beam profiler 46 is provided inside the implantation processing chamber 14. The beam profiler 46 is a beam measurement device for measuring the scanning beam SB at a position of the surface of the workpieces W1, W2. The beam profiler 46 is configured to be movable in a vertical direction (y direction) by an operation of a profiler driver 47. The beam profiler 46 is retracted from an implantation position at which the workpiece W1 or W2 is positioned during the ion implantation, and is inserted into the implantation position in a case in which the workpiece W1 or W2 is not at the implantation position.

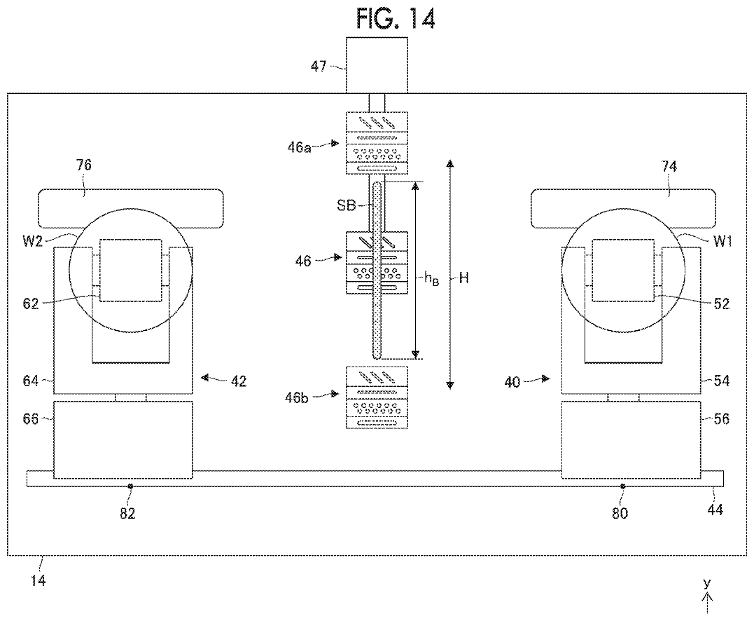

FIG. 14 is a front view schematically showing a movable range of the beam profiler 46, and is the same as FIG. 3 with the addition of the beam profiler 46. FIG. 14 shows the beam profiler 46 in a state of being inserted into the implantation position. The beam profiler 46 is movable in the vertical direction (y direction) as indicated by an arrow H by the operation of the profiler driver 47. The beam profiler 46 is configured to be movable over a size h_{B} of the irradiation range of the scanning beam SB in the vertical direction, and is configured to be movable between an upper end position 46a on a vertical upper side of the scanning beam SB and a lower end position 46b on a vertical lower side of the scanning beam SB. In a case in which the beam profiler 46 is retracted from the implantation position, the beam profiler 46 is disposed at, for example, the upper end position 46a.

The beam profiler 46 includes a profiler cup that is a Faraday cup for measuring a beam current of the scanning beam SB. The beam profiler 46 can measure the beam current over the entire beam scanning range of the scanning beam SB by measuring the beam current while moving in the vertical direction (y direction). The beam profiler 46 may be a measurement device that measures a beam current density distribution of the scanning beam SB in the vertical direction (y direction).

The beam profiler 46 may include an angle measurement device for measuring angle information of the scanning beam SB. The angle measurement device may include a first angle measurement device that can measure angle information of the scanning beam SB in a horizontal direction (x direction), and a second angle measurement device that can measure angle information of the scanning beam SB in a vertical direction (y direction). The beam profiler 46 may be a measurement device that measures angle information in the x direction and angle information in the y direction, and may measure an angle centroid, a convergence/divergence angle, or the like as the angle information.

Hereinafter, an angle measurement device that can be used in the beam profiler 46 will be described.

### First Embodiment

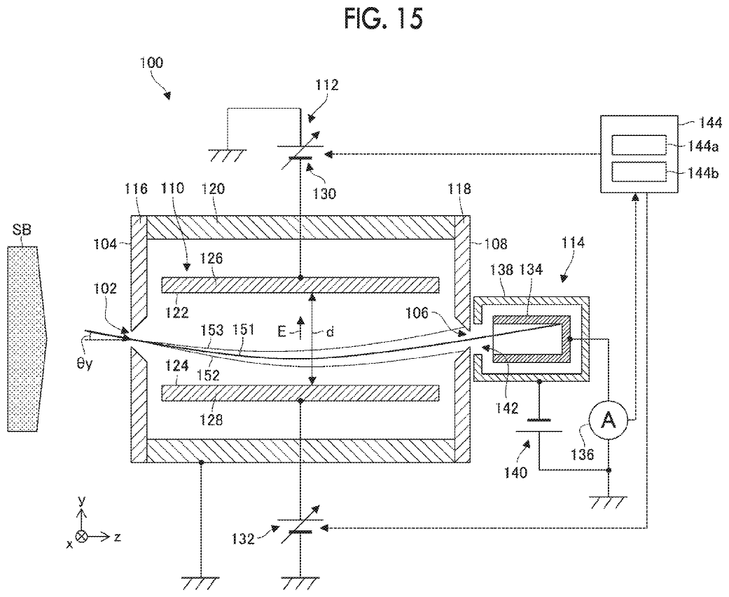

FIG. 15 is a cross-sectional view showing a schematic configuration of an angle measurement device 100 according to the first embodiment. The angle measurement device 100 is configured to measure angle information of the scanning beam SB in a first direction. FIG. 15 shows a case in which the first direction is parallel to the scanning direction (y direction), but a direction (that is, the first direction) of the angle information measured by the angle measurement device 100 is not particularly limited, and the first direction may be oblique to the scanning direction.

The angle measurement device 100 includes an incidence surface 104 having an incidence opening 102, an emission surface 108 having an emission opening 106, an electrode assembly 110, a power supply 112, and a current measurement device 114.

The angle measurement device 100 can include a front panel 116 having the incidence surface 104. The incidence opening 102 is formed to penetrate the front panel 116. The incidence opening 102 allows a part of the scanning beam SB incident on the incidence surface 104 to pass through. The incidence opening 102 has an opening shape in which at least an opening width in the first direction is short.

The angle measurement device 100 can include a back panel 118 having the emission surface 108. The back panel 118 is disposed away from the front panel 116 in a traveling direction (that is, the z direction) of the scanning beam SB. The emission opening 106 is formed to penetrate the back panel 118. The emission opening 106 allows a part of the ion beam passing through the incidence opening 102 to pass through. The emission opening 106 has an opening shape in which at least an opening width in the first direction is short, as in the incidence opening 102. The emission opening 106 is disposed such that positions in the x direction and the y direction orthogonal to the traveling direction (z direction) of the scanning beam SB match the incidence opening 102, for example.

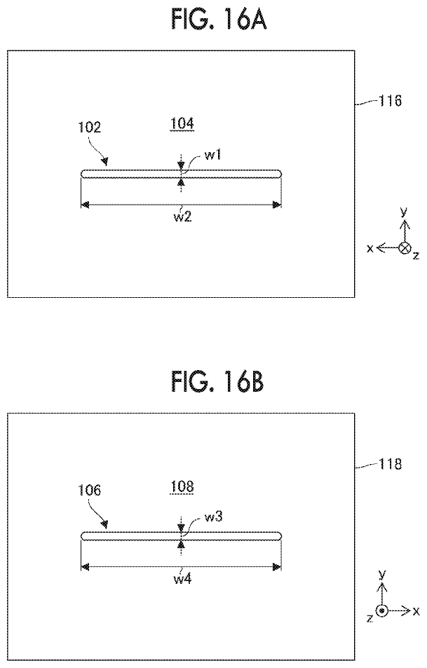

FIG. 16A is a plan view showing a schematic configuration of the incidence surface 104 having the incidence opening 102, and FIG. 16B is a plan view showing a schematic configuration of the emission surface 108 having the emission opening 106. The incidence opening 102 can have a slit shape in which an opening width w1 in the first direction (for example, the y direction) is short and an opening width w2 in a direction (for example, the x direction) orthogonal to the first direction is long. The incidence opening 102 is, for example, a slit having a slit width direction parallel to the scanning direction of the scanning beam SB.

The opening width w1 of the incidence opening 102 in the slit width direction is, for example, 10 mm or less, 5 mm or less, or 3 mm or less. The opening width w1 of the incidence opening 102 in the slit width direction is, for example, 0.1 mm or more, 0.5 mm or more, or 1 mm or more. The opening width w2 of the incidence opening 102 in the slit length direction orthogonal to the first direction is, for example, longer than a beam width of the scanning beam SB in the x direction. The opening width w2 of the incidence opening 102 in the slit length direction is, for example, 10 mm or more, 20 mm or more, or 30 mm or more. The opening width w2 of the incidence opening 102 in the slit length direction is, for example, 200 mm or less, 150 mm or less, or 100 mm or less.

The emission opening 106 can have the same shape and size as the incidence opening 102. The emission opening 106 is, for example, a slit having a slit width direction parallel to the scanning direction of the scanning beam SB. The opening width w3 of the emission opening 106 in the slit width direction may be the same as the opening width w1 of the incidence opening 102 in the slit width direction. The opening width w4 of the emission opening 106 in the slit length direction may be the same as the opening width w2 of the incidence opening 102 in the slit length direction.

The opening width w2 of the incidence opening 102 in the direction orthogonal to the first direction may be shorter than the beam width of the scanning beam SB. The opening width w2 of the incidence opening 102 in the direction orthogonal to the first direction may be on the same level as the opening width w1 of the incidence opening 102 in the first direction. In this case, the opening shape of the incidence opening 102 may be a square shape or a circular shape instead of the slit shape. Similarly, the opening width w4 of the emission opening 106 in the direction orthogonal to the first direction may be shorter than the beam width of the scanning beam SB in the direction orthogonal to the first direction. The opening width w4 of the emission opening 106 in the direction orthogonal to the first direction may be on the same level as the opening width w3 of the emission opening 106 in the first direction. In this case, the opening shape of the emission opening 106 may be a square shape or a circular shape instead of the slit shape.

Returning to FIG. 15, the electrode assembly 110 is provided between the incidence surface 104 and the emission surface 108. The electrode assembly 110 includes a first electrode surface 122 and a second electrode surface 124 that face each other in the first direction across the ion beam from the incidence opening 102 toward the emission opening 106. The first electrode surface 122 and the second electrode surface 124 face each other to be parallel to each other. A facing distance d of the first electrode surface 122 and the second electrode surface 124 in the first direction is sufficiently larger than the opening widths w1, w3 of the incidence opening 102 and the emission opening 106 in the first direction. Here, the term “sufficiently large” means that the facing distance d is large to the extent that the transport of the ion beam from the incidence opening 102 toward the emission opening 106 is not hindered. The facing distance d of the first electrode surface 122 and the second electrode surface 124 in the first direction is, for example, 5 mm or more, 10 mm or more, or 15 mm or more. The facing distance d of the first electrode surface 122 and the second electrode surface 124 in the first direction is, for example, 50 mm or less, 30 mm or less, or 20 mm or less.

The electrode assembly 110 can include a first electrode body 126 having the first electrode surface 122 and a second electrode body 128 having the second electrode surface 124. A side plate 120 for surrounding the first electrode body 126 and the second electrode body 128 can be provided around the electrode assembly 110. The side plate 120 can be configured to extend in a tubular shape from the front panel 116 toward the back panel 118. The front panel 116, the back panel 118, and the side plate 120 can constitute a housing that accommodates the electrode assembly 110. The front panel 116, the back panel 118, and the side plate 120 can be grounded to have a ground potential.

The power supply 112 applies a voltage to the electrode assembly 110 to generate a potential difference ΔV between the first electrode surface 122 and the second electrode surface 124. The power supply 112 is a variable voltage source, and a potential difference ΔV between the first electrode surface 122 and the second electrode surface 124 is variable. The power supply 112 can include a first power supply 130 that is coupled to the first electrode surface 122 or the first electrode body 126, and a second power supply 132 that is coupled to the second electrode surface 124 or the second electrode body 128. The power supply 112 may include only one of the first power supply 130 or the second power supply 132. In this case, the electrode surface or the electrode body to which the first power supply 130 or the second power supply 132 is not coupled may be grounded to have a ground potential.

The power supply 112 applies a voltage such that the potential difference ΔV between the first electrode surface 122 and the second electrode surface 124 is, for example, 500 V or more, 1000 V or more, or 2000 V or more at maximum. Each of the first power supply 130 and the second power supply 132 is configured to be able to apply a voltage having an absolute value of, for example, 1000 V at maximum. For example, by setting the applied voltage of the first power supply 130 to −1000 V and setting the applied voltage of the second power supply 132 to +1000 V, the potential difference ΔV between the first electrode surface 122 and the second electrode surface 124 can be set to 2000 V. The power supply 112 changes the applied voltage based on, for example, a command value from the controller 18.

The electrode assembly 110 and the power supply 112 function as a deflection device that deflects the ion beam from the incidence opening 102 toward the emission opening 106. FIG. 15 shows trajectories 151, 152, 153 of the ion beam deflected by an electric field E due to the potential difference ΔV between the first electrode surface 122 and the second electrode surface 124. The magnitude of the electric field E can be represented by E=ΔV/d using the potential difference ΔV between the first electrode surface 122 and the second electrode surface 124 and the facing distance d. A trajectory 151 indicated by a thick line indicates an ion beam that can pass through both the incidence opening 102 and the emission opening 106. Trajectories 152, 153 indicated by thin lines indicate the ion beams that cannot pass through the emission opening 106 and is blocked by the emission surface 108 or the back panel 118. The ion beam along the trajectory 152 cannot pass through the emission opening 106 because an angle θy in the first direction is slightly larger than that of the ion beam along the trajectory 151. In addition, the ion beam along the trajectory 153 cannot pass through the emission opening 106 because an angle θy in the first direction is slightly smaller than that of the ion beam along the trajectory 151. Therefore, the ion beam emitted from the emission opening 106 is limited to the ion beam having the angle θy in the first direction within a specific range at the incidence opening 102.

The angle θy in the first direction of the ion beam emitted from the emission opening 106 at the incidence opening 102 changes due to the electric field E between the first electrode surface 122 and the second electrode surface 124, that is, the potential difference ΔV. Therefore, by changing the potential difference ΔV between the first electrode surface 122 and the second electrode surface 124, the angle θy in the first direction of the ion beam emitted from the emission opening 106 at the incidence opening 102 can be changed.

The current measurement device 114 detects the ion beam passing through the emission opening 106 to measure the beam current value. The current measurement device 114 includes a Faraday cup 134 for detecting the ion beam and an ammeter 136 coupled to the Faraday cup 134. The current measurement device 114 can further include a suppression electrode 138 disposed between the emission surface 108 and the Faraday cup 134. The suppression electrode 138 is coupled to a suppression power supply 140 for applying a predetermined suppression voltage. The suppression electrode 138 has a through opening 142 through which the ion beam from the emission opening 106 toward the Faraday cup 134 passes. The through opening 142 has an opening shape having a size sufficiently larger than the emission opening 106 such that the ion beam from the emission opening 106 toward the Faraday cup 134 is not blocked. A configuration in which a suppression magnetic field for suppressing the movement of electrons is applied may be adopted instead of the configuration in which the suppression electric field for suppressing the movement of electrons is applied.

The angle measurement device 100 can further include a measurement controller 144. The measurement controller 144 includes a processor 144a and a memory 144b. The measurement controller 144 controls the entire operation of the angle measurement device 100 by executing a predetermined program stored in the memory 144b by the processor 144a, for example. The measurement controller 144 can be configured in the same manner as the controller 18 described above, for example. The angle measurement device 100 may be operated by the controller 18 in addition to or instead of the measurement controller 144.

The measurement controller 144 outputs a command value for setting the applied voltage of the power supply 112. The measurement controller 144 outputs, for example, a command value for applying a variable voltage to the electrode assembly 110, and changes the value of the potential difference ΔV between the first electrode surface 122 and the second electrode surface 124 over time. The measurement controller 144 may output, for example, a command value for periodically changing the value of the potential difference ΔV between the first electrode surface 122 and the second electrode surface 124. The measurement controller 144 may output a command value indicating a time-series value of the potential difference ΔV between the first electrode surface 122 and the second electrode surface 124.

The measurement controller 144 acquires the beam current value I measured by the current measurement device 114. The measurement controller 144 calculates the angle information of the scanning beam SB in the first direction using the value of the potential difference ΔV between the first electrode surface 122 and the second electrode surface 124 based on the command value and the acquired beam current value I. The measurement controller 144 calculates the angle θy in the first direction of the ion beam detected by the current measurement device 114 at the incidence opening 102 using, for example, the beam energy of the scanning beam SB and the value of the potential difference ΔV between the first electrode surface 122 and the second electrode surface 124. The measurement controller 144 calculates the intensity of the angle component of the scanning beam SB in the first direction by associating the calculated angle θy with the acquired beam current value. The measurement controller 144 can calculate the angle distribution of the scanning beam SB in the first direction by associating the values of the plurality of potential differences ΔVi (i=1 to n) between the first electrode surface 122 and the second electrode surface 124 with the plurality of beam current values Ii (i=1 to n) corresponding to the values of the plurality of potential differences ΔVi.

The measurement controller 144 may change the value of the potential difference ΔV between the first electrode surface 122 and the second electrode surface 124 in correspondence with a scanning period Ts of the scanning beam SB. The measurement controller 144 may fix the potential difference ΔV between the first electrode surface 122 and the second electrode surface 124 at a timing at which the scanning beam SB is incident on the angle measurement device 100 (specifically, the incidence surface 104). In other words, the measurement controller 144 may change the potential difference ΔV between the first electrode surface 122 and the second electrode surface 124 at a timing at which the scanning beam SB is not incident on the angle measurement device 100 (specifically, the incidence surface 104).

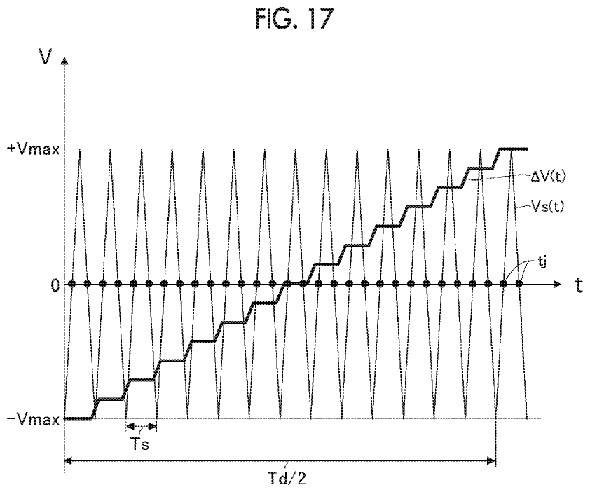

FIG. 17 is a graph showing an example of a scanning voltage waveform Vs(t) of the scanning beam SB and a time waveform ΔV(t) of the potential difference in the angle measurement device 100. A vertical axis of the graph is a voltage value V, and maximum absolute values of the scanning voltage Vs and the potential difference ΔV are normalized as Vmax. A scanning frequency fs (=1/Ts) of the scanning voltage waveform Vs(t) corresponding to the scanning period Ts is, for example, 10 Hz or more or 100 Hz or more, and is, for example, 100 kHz or less or 10 kHz or less. An example of the scanning frequency fs is 1 kHz.

In FIG. 17, measurement timings tj (for example, j=1 to 2n) at which the scanning beam SB is incident on the angle measurement device 100 are represented by black circles. In the example of FIG. 17, the angle measurement device 100 is positioned at the center of the scanning direction (that is, the y direction) of the scanning beam SB, and the scanning beam SB is incident on the angle measurement device 100 when the scanning voltage Vs=0. The position of the angle measurement device 100 is not particularly limited, and the angle measurement device 100 may be disposed such that the scanning beam SB is incident on the angle measurement device 100 at a timing at which the scanning voltage Vs is a specific value other than 0.

The time waveform ΔV(t) of the potential difference in the angle measurement device 100 is changed in stages in correspondence with the scanning period Ts. The value of the potential difference ΔV(t) is fixed at the measurement timing tj at which the scanning beam SB is incident on the angle measurement device 100, and is changed at a timing different from the measurement timing tj. In the example of FIG. 17, the value of the potential difference ΔV is changed at a timing at which the scanning voltage Vs=−Vmax. The timing at which the value of the potential difference ΔV is changed is not particularly limited, and any timing different from the measurement timing tj can be selected, and may be, for example, a timing at which the scanning voltage Vs=+Vmax.

In the example of FIG. 17, the value of the potential difference ΔV is changed for each scanning period Ts, and the voltage value is set to 15 stages from-Vmax to +Vmax. In the example of FIG. 17, only the process in which the value of the potential difference ΔV changes from-Vmax to +Vmax is shown, but the value of the potential difference ΔV may be changed from +Vmax to −Vmax, or may be changed from-Vmax to +Vmax and then changed from +Vmax to-Vmax. In addition, the potential difference ΔV may be repeatedly changed between-Vmax and +Vmax. The time in which the value of the potential difference ΔV changes from-Vmax to +Vmax corresponds to half (Td/2) of a deflection period Td for changing the potential difference ΔV. In the example of FIG. 17, the deflection period Td is 28 times the scanning period Ts (that is, Td=28×Ts). Therefore, the deflection frequency fd (=1/Td) corresponding to the deflection period Td is 1/28 of the scanning frequency fs.

The number of stages of the voltage value set in the time waveform ΔV(t) of the potential difference is not particularly limited, but can be, for example, 10 or more, 15 or more, or 20 or more, and can be, for example, 100 or less, 50 or less, or 30 or less. By increasing the number of stages, the measurement accuracy (for example, the angle resolution) can be improved, but the time required for the measurement increases. Therefore, the number of stages of the time waveform ΔV(t) of the potential difference can be appropriately set according to a balance between the required angle resolution and the measurement time. In addition, the value of the potential difference ΔV may be changed for each half of the scanning period Ts instead of changing the value of the potential difference ΔV for each scanning period Ts. In this case, the time required for the measurement can be shortened. In addition, the value of the potential difference ΔV may be changed for each integer multiple (for example, k·Ts) of the scanning period Ts. In this case, since the number of measurements of the scanning beam SB in one stage increases, the measurement accuracy can be improved. The deflection frequency fd can be set to, for example, 1/1000 or more, 1/500 or more, or 1/200 or more of the scanning frequency fs, and can be set to, for example, 1/10 or less, 1/20 or less, or 1/50 or less of the scanning frequency fs. An example of the deflection frequency fd is about 1/100 of the scanning frequency fs, and is, for example, about 10 Hz. It is preferable that the deflection frequency fd is set to be different from the scanning frequency fs.

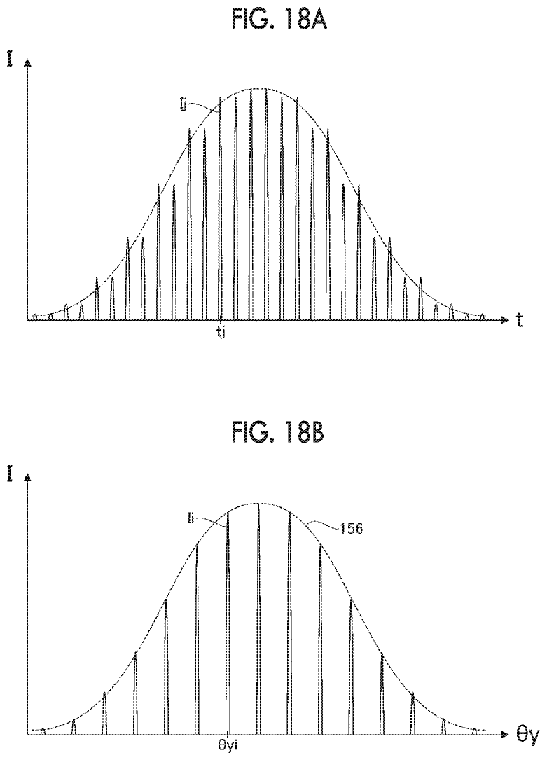

FIG. 18A is a graph showing an example of a time waveform I(t) of the beam current detected by the angle measurement device 100. FIG. 18A corresponds to the time waveform I(t) of the beam current in a case in which the time waveform of the potential difference ΔV shown in FIG. 17 is applied. The time waveform I(t) of the beam current is composed of time-series values of the pulse-shaped beam current Ij measured at each of the plurality of measurement timings tj. In the example of FIG. 18A, the scanning beam SB is incident on the angle measurement device 100 once in each of the reciprocating directions (a total of two times) while the value of the potential difference ΔVi (=ΔV(t)) is fixed, so that two pulse-shaped beam currents Ij are measured for a specific value of the potential difference ΔVi. Using the two beam current values Ij, for example, by adding or averaging the two beam current values Ij, a beam current value Ii corresponding to the specific value of the potential difference ΔVi can be obtained. Further, by converting the potential difference ΔVi into the angle θyi, the beam current value Ii corresponding to the angle θyi can be obtained. FIG. 18B is a graph showing an example of the angle distribution of the scanning beam calculated using the time waveform I(t) of the beam current of FIG. 18A, and for example, an angle distribution as indicated by a broken line 156 can be calculated.

According to the present embodiment, the angle information of the scanning beam SB in the first direction can be acquired with high accuracy in a short time. Since the scanning beam SB incident on the angle measurement device 100 is reciprocatingly scanned by the beam scanner 28 (also referred to as a beam scanner) disposed upstream of the angle measurement device 100, the entire beam can be measured without moving the angle measurement device 100. In addition, since the deflection period Td required for acquiring the angle distribution can be set to 1 second or less or 0.1 second or less, the angle distribution of the scanning beam SB in the first direction can be measured in a very short time. In addition, since the angle resolution can be improved by increasing the number of stages of the potential difference ΔVi, the measurement accuracy can be improved as compared with the related art configuration in which the angle distribution is measured by arranging a plurality of electrode bodies.

In the above-described embodiment, a case has been described in which the deflection frequency fd is smaller than the scanning frequency fs, that is, the deflection period Td is larger than the scanning period Ts. In the modification example, the deflection frequency fd may be larger than the scanning frequency fs, and the deflection period Td may be smaller than the scanning period Ts. For example, the scanning frequency fs may be set to a small value such as 10 Hz or less, and the deflection frequency fd may be set to, for example, 10 times or more, 20 times or more, or 50 times or more of the scanning frequency fs, and may be set to, for example, 1000 times or less, 500 times or less, or 200 times or less. The deflection frequency fd may be, for example, 100 Hz or more, 500 Hz or more, or 1 kHz or more, and may be, for example, 100 kHz or less, 50 kHz or less, or 10 kHz or less. In this case, a plurality of beam current values Ii corresponding to a plurality of potential differences ΔVi can be acquired while the scanning beam SB is scanned in the reciprocating or one-way direction. Therefore, even in this case, the angle distribution of the scanning beam SB in the first direction can be measured in the scanning period Ts of 1 second or less or 0.1 second or less. In this case, the deflection frequency fd may be set not to be an integer multiple of the scanning frequency fs.

In the above-described embodiment, a case has been described in which the scanning voltage waveform Vs(t) is a triangular wave, but the shape of the scanning voltage waveform Vs(t) is not particularly limited, and may be a sine wave, a modulated wave of a triangular wave or a sine wave, or a waveform that changes in a stepwise manner. In addition, in the above-described embodiment, a case has been described in which the time waveform ΔV(t) of the potential difference changes in a stepwise manner, but the shape of the time waveform ΔV(t) of the potential difference is not limited, and may be a triangular wave, a sine wave, or a modulated wave of a triangular wave or a sine wave. Each of the scanning voltage waveform Vs(t) and the time waveform ΔV(t) of the potential difference may be any waveform that periodically changes, which is represented by a stepwise waveform, a triangular wave, a sine wave, or a modulated wave of a triangular wave or a sine wave, and the deflection frequency fd of the time waveform ΔV(t) of the potential difference may be set not to be an integer multiple of the scanning frequency fs of the scanning voltage waveform Vs(t), and the scanning frequency fs may be set not to be an integer multiple of the deflection frequency fd.

In the above-described embodiment, a case has been described in which the scanning beam SB is the measurement target, but the angle measurement device 100 may measure the ion beam that is not scanned by the beam scanner. In this case, in order to measure the entire ion beam that is not scanned, the measurement of the ion beam may be executed in combination with moving the angle measurement device 100 in the scanning direction (y direction). In addition, the measurement of the scanning beam SB may be executed in combination with moving the angle measurement device 100 in the scanning direction (y direction).

### Second Embodiment

The angle measurement device according to the second embodiment includes an incidence surface, an emission surface, an electrode assembly, a power supply, and a current measurement device, as in the first embodiment. The second embodiment is different from the first embodiment in that a plurality of incidence openings are provided in the incidence surface and a plurality of emission openings are provided in the emission surface. Hereinafter, the angle measurement device according to the second embodiment will be described with the differences from the first embodiment as the main point, and the common points will be appropriately omitted from the description.

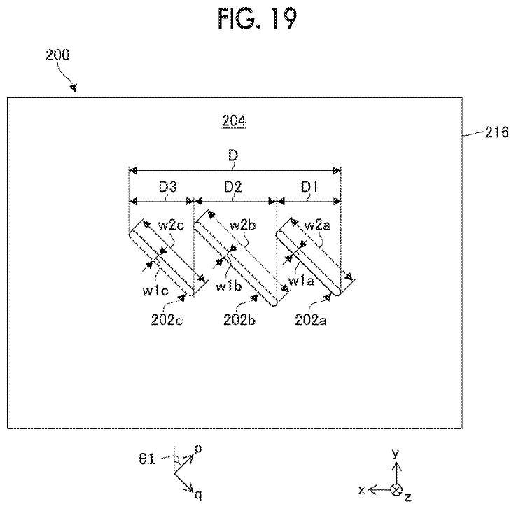

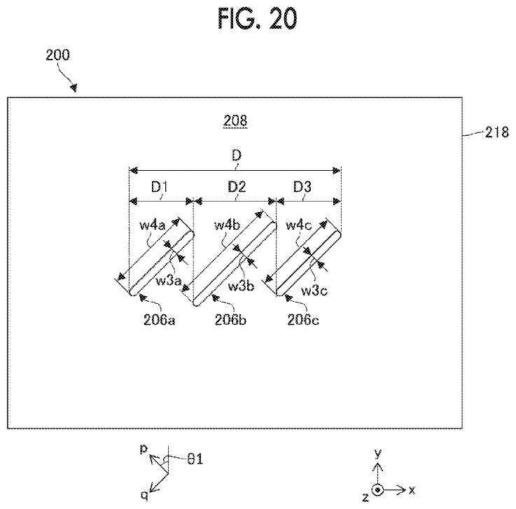

FIGS. 19 and 20 are plan views showing a schematic configuration of an angle measurement device 200 according to the second embodiment. FIG. 19 shows a view of an incidence surface 204 having a plurality of incidence openings 202a, 202b, 202c as viewed from an upstream side in a beam traveling direction (z direction). The plurality of incidence openings 202a to 202c are disposed side by side in a direction (x direction) orthogonal to the scanning direction of the scanning beam SB in the measurement range D. Opening ranges D1, D2, D3 in the x direction in which the plurality of incidence openings 202a to 202c are provided are set to be continuous without a gap in the x direction and not to overlap in the x direction. The plurality of incidence openings 202a to 202c are formed to penetrate a front panel 216 having the incidence surface 204.

The plurality of incidence openings 202a to 202c have a slit shape in which opening widths w1a, w1b, w1c in a p direction oblique to the scanning direction (y direction) are short and opening widths w2a, w2b, w2c in a q direction orthogonal to the p direction are long. Opening widths w1a to w1c of the plurality of incidence openings 202a to 202c in the slit width direction (that is, the p direction) are common to each other. Opening widths w2a, w2b, w2c of the plurality of incidence openings 202a to 202c in the slit length direction (q direction) may be common to each other or may be different from each other. In the example of FIG. 19, the opening width w2b of the second incidence opening 202b disposed at the center in the slit length direction is longer than the opening widths w2a, w2c of the first incidence opening 202a and the third incidence opening 202c disposed on the left and right sides in the slit length direction.

FIG. 20 shows a view of an emission surface 208 having a plurality of emission openings 206a, 206b, 206c as viewed from a downstream side in the beam traveling direction (z direction). The plurality of emission openings 206a to 206c can have the same shape and size as the corresponding incidence openings 202a to 202c. The plurality of emission openings 206a to 206c are disposed such that positions in the x direction and the y direction orthogonal to the traveling direction of the scanning beam SB match those of the corresponding incidence openings 202a to 202c. Opening widths w3a, w3b, w3c of the plurality of emission openings 206a to 206c in the slit width direction may be the same as the opening widths w1a to w1c of the corresponding incidence openings 202a to 202c in the slit width direction. Opening widths w4a, w4b, w4c of the plurality of emission openings 206a to 206c in the slit length direction may be the same as the opening widths w2a to w2c of the corresponding incidence openings 202a to 202c in the slit length direction.

In the example shown in FIGS. 19 and 20, the angle measurement device 200 includes three incidence openings 202a to 202c and three emission openings 206a to 206c. That is, the angle measurement device 200 includes the first incidence opening 202a, the second incidence opening 202b, and the third incidence opening 202c provided in the incidence surface 204, and includes the first emission opening 206a, the second emission opening 206b, and the third emission opening 206c provided in the emission surface 208. The number of each of the plurality of incidence openings and the plurality of emission openings included in the angle measurement device 200 is not limited to three, and may be two or four or more.

In the example shown in FIGS. 19 and 20, an angle θ1 between the slit width direction (p direction) and the scanning direction (y direction) of the plurality of incidence openings 202a to 202c and the plurality of emission openings 206a to 206c is 45 degrees. The angle θ1 between the slit width direction (p direction) and the scanning direction (y direction) is not particularly limited, and may be, for example, 5 degrees or more, 15 degrees or more, or 30 degrees or more, and may be, for example, 85 degrees or less, 75 degrees or less, or 60 degrees or less.

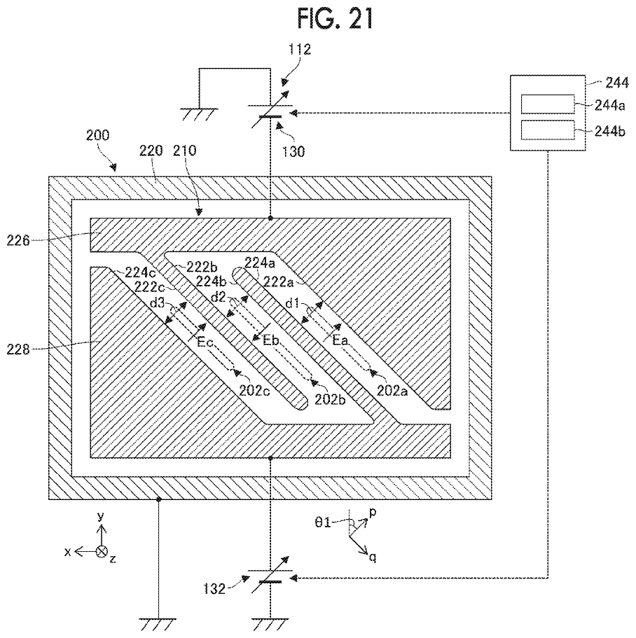

FIG. 21 is a cross-sectional view showing a schematic configuration of an electrode assembly 210 according to the second embodiment. The electrode assembly 210 is disposed between the incidence surface 204 and the emission surface 208. FIG. 21 is a cross-sectional view orthogonal to the traveling direction (z direction) of the scanning beam SB, unlike FIG. 15 described above. In FIG. 21, positions of the plurality of incidence openings 202a to 202c are indicated by broken lines.

The electrode assembly 210 includes a first electrode surface 222a, a second electrode surface 224a, a third electrode surface 224b, a fourth electrode surface 222b, a fifth electrode surface 222c, and a sixth electrode surface 224c. The first electrode surface 222a and the second electrode surface 224a face each other in a first direction at a first distance d1 across the ion beam from the first incidence opening 202a toward the first emission opening 206a. The first direction is parallel to the slit width direction (p direction) of the first incidence opening 202a. The third electrode surface 224b and the fourth electrode surface 222b face each other in a second direction at a second distance d2 across the ion beam from the second incidence opening 202b toward the second emission opening 206b. The second direction is parallel to the slit width direction (p direction) of the second incidence opening 202b. The fifth electrode surface 222c and the sixth electrode surface 224c face each other in a third direction at a third distance d3 across the ion beam from the third incidence opening 202c toward the third emission opening 206c. The third direction is parallel to the slit width direction (p direction) of the third incidence opening 202c. Therefore, in the example shown in FIG. 21, the first direction, the second direction, and the third direction are parallel to each other. In addition, the first distance d1, the second distance d2, and the third distance d3 are the same as each other.

The power supply 112 is connected to the electrode assembly 210. The power supply 112 is configured in the same manner as in the first embodiment. The power supply 112 generates a potential difference between two electrode surfaces facing each other. The power supply 112 generates a first potential difference between the first electrode surface 222a and the second electrode surface 224a, generates a second potential difference between the third electrode surface 224b and the fourth electrode surface 222b, and generates a third potential difference between the fifth electrode surface 222c and the sixth electrode surface 224c.

The electrode assembly 210 includes a first electrode body 226 and a second electrode body 228. The first electrode body 226 has the first electrode surface 222a, the fourth electrode surface 222b, and the fifth electrode surface 222c. The second electrode body 228 has the second electrode surface 224a, the third electrode surface 224b, and the sixth electrode surface 224c. The first power supply 130 is coupled to the first electrode body 226, and the second power supply 132 is coupled to the second electrode body 228. In this case, the magnitudes of the first potential difference, the second potential difference, and the third potential difference are the same. However, the directions of the electric fields generated between the two facing electrode surfaces may be different. A direction of a first electric field Ea based on the first potential difference between the first electrode surface 222a and the second electrode surface 224a is the same as a direction of a third electric field Ec based on the third potential difference between the fifth electrode surface 222c and the sixth electrode surface 224c, but is opposite (or antiparallel) to a direction of a second electric field Eb based on the second potential difference between the third electrode surface 224b and the fourth electrode surface 222b.

A side plate 220 for surrounding the first electrode body 226 and the second electrode body 228 can be provided around the electrode assembly 210. The side plate 220 can be configured to extend in a tubular shape from the front panel 216 toward the back panel 218. The front panel 216, the back panel 218, and the side plate 220 can constitute a housing that accommodates the electrode assembly 210. The front panel 216, the back panel 218, and the side plate 220 can be grounded to have a ground potential.

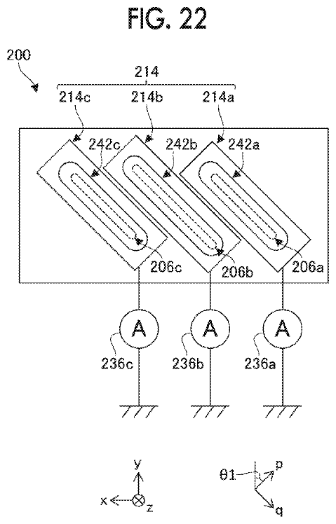

FIG. 22 is a plan view showing a schematic configuration of a current measurement device 214 according to the second embodiment. The current measurement device 214 includes a plurality of current measurement devices 214a, 214b, 214c. The plurality of current measurement devices 214a to 214c are configured to detect the ion beam passing through the corresponding emission openings 206a to 206c to measure the beam current value. In FIG. 22, positions of the plurality of emission openings 206a to 206c are indicated by broken lines.

The current measurement device 214 can include a first current measurement device 214a, a second current measurement device 214b, and a third current measurement device 214c. The first current measurement device 214a detects the ion beam emitted from the first emission opening 206a to measure the first beam current value. The second current measurement device 214b detects the ion beam emitted from the second emission opening 206b to measure the second beam current value. The third current measurement device 214c detects the ion beam emitted from the third emission opening 206c to measure the third beam current value.

Each of the plurality of current measurement devices 214a to 214c can be configured in the same manner as the current measurement device 114 according to the first embodiment described above. Each of the plurality of current measurement devices 214a to 214c can include a Faraday cup, an ammeter 236a to 236c coupled to the Faraday cup, a suppression electrode having through openings 242a, 242b, 242c, and a suppression power supply coupled to the suppression electrode.

The angle measurement device 200 can further include a measurement controller 244 (see FIG. 21). The measurement controller 244 includes a processor 244a and a memory 244b. The measurement controller 244 can be configured in the same manner as the measurement controller 144 according to the first embodiment described above. The measurement controller 244 outputs a command value for applying a variable voltage to the electrode assembly 210, and changes the potential difference ΔV between the two facing electrode surfaces over time.

The measurement controller 244 acquires the beam current values measured by the plurality of current measurement devices 214a to 214c, and calculates the angle information using the acquired beam current values. The measurement controller 244 can total, for example, the first beam current value Ii1, the second beam current value Ii2, and the third beam current value Ii3 measured for a specific potential difference ΔVi, and calculate the intensity of the angle component using the total beam current value Ii (=Ii1+Ii2+Ii3). The measurement controller 244 can obtain the beam current value Ii corresponding to the angle θpi by converting the potential difference ΔVi into the angle θpi in the p direction. As a result, the angle information in the p direction oblique to the scanning direction (y direction) can be obtained.

In the second embodiment, the current measurement device 214 may be configured of only a single current measurement device instead of including the plurality of current measurement devices 214a to 214c. In this case, the current measurement device 214 may include a single Faraday cup that totals and detects the plurality of ion beams emitted from each of the plurality of emission openings 206a to 206c. That is, the single Faraday cup is configured to detect an ion beam group consisting of all of the ion beam emitted from the first emission opening 206a, the ion beam emitted from the second emission opening 206b, and the ion beam emitted from the third emission opening 206c. In this case, the total value Ii (=Ii1+Ii2+Ii3) of the first beam current value Ii1, the second beam current value Ii2, and the third beam current value Ii3 can be measured using the single Faraday cup.

According to the present embodiment, in a case in which the plurality of incidence openings 202a to 202c and the plurality of emission openings 206a to 206c are provided, the configuration of the electrode assembly can be simplified by using the electrode body in which the plurality of electrode surfaces to which the common applied voltage is applied are integrated.

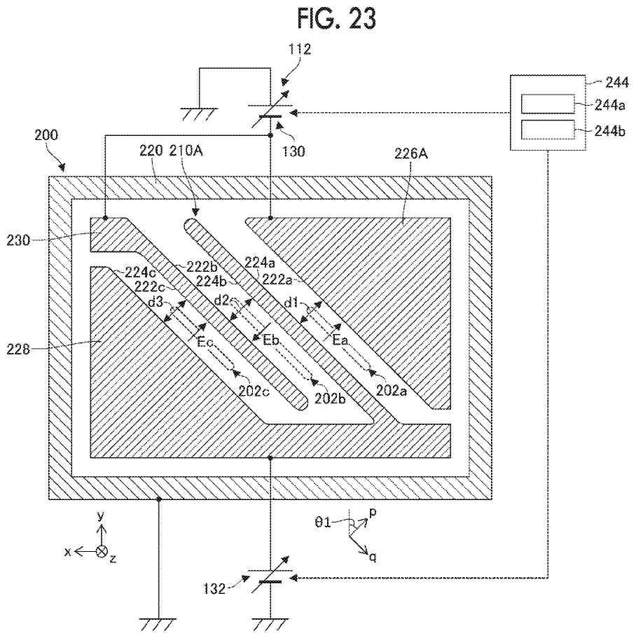

FIG. 23 is a cross-sectional view showing a schematic configuration of an electrode assembly 210A according to the modification example. The electrode assembly 210A includes a first electrode surface 222a, a second electrode surface 224a, a third electrode surface 224b, a fourth electrode surface 222b, a fifth electrode surface 222c, and a sixth electrode surface 224c, as in the electrode assembly 210 shown in FIG. 21 described above.

The electrode assembly 210A includes a first electrode body 226A, the second electrode body 228, and a third electrode body 230. The first electrode body 226A has the first electrode surface 222a. The second electrode body 228 has the second electrode surface 224a, the third electrode surface 224b, and the sixth electrode surface 224c. The third electrode body 230 has the fourth electrode surface 222b and the fifth electrode surface 222c. The first power supply 130 is coupled to the first electrode body 226A and the third electrode body 230. The second power supply 132 is coupled to the second electrode body 228.

Even in a case in which the electrode assembly 210A according to the present modification example is used, the same effect as that of the second embodiment described above can be achieved.

### Third Embodiment

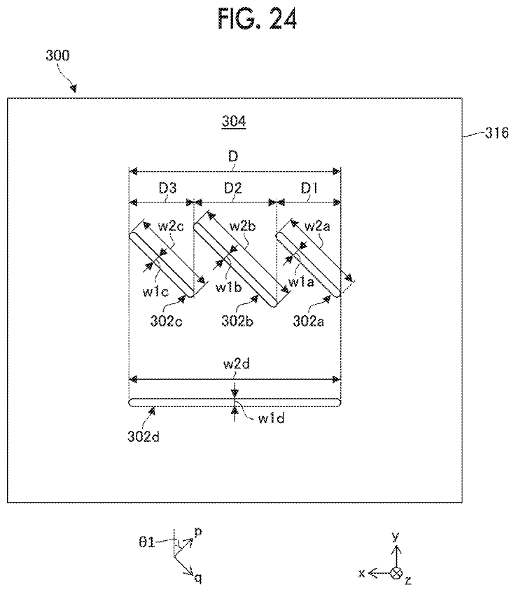

FIG. 24 is a plan view showing a schematic configuration of an incidence surface 304 of an angle measurement device 300 according to the third embodiment. The angle measurement device 300 according to the third embodiment is configured to measure angle information of the scanning beam SB in the scanning direction (y direction) and angle information of the scanning beam SB in the direction (x direction) orthogonal to the scanning direction. Hereinafter, the angle measurement device 300 according to the third embodiment will be described with the differences from the above-described embodiment as the main point, and the common points will be appropriately omitted from the description.

FIG. 24 shows a view of an incidence surface 304 having a plurality of incidence openings 302a to 302d as viewed from an upstream side in a beam traveling direction (z direction). A plurality of incidence openings 302a, 302b, 302c, 302d are formed in the incidence surface 304. The first incidence opening 302a, the second incidence opening 302b, and the third incidence opening 302c can be configured in the same manner as the plurality of incidence openings 202a to 202c according to the second embodiment described above. The slit width direction of the first incidence opening 302a, the second incidence opening 302b, and the third incidence opening 302c is a p direction oblique to the scanning direction (y direction). The fourth incidence opening 302d is disposed in the measurement range D in which the first incidence opening 302a, the second incidence opening 302b, and the third incidence opening 302c are formed, and is disposed at a position away from the first incidence opening 302a, the second incidence opening 302b, and the third incidence opening 302c in the scanning direction (y direction). The slit width direction of the fourth incidence opening 302d is parallel to the scanning direction (y direction). The opening width w2d of the fourth incidence opening 302d in the slit length direction matches, for example, the measurement range D. Opening widths w1a, w1b, w1c, and w1d of the plurality of incidence openings 302a, 302b, 302c, 302d in the slit width direction are common to each other. The plurality of incidence openings 302a to 302d are formed to penetrate a front panel 316 having the incidence surface 304.

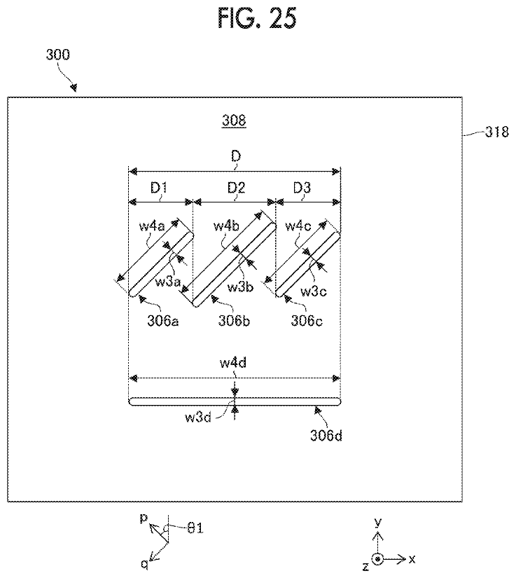

FIG. 25 is a plan view showing a schematic configuration of an emission surface 308 of the angle measurement device 300 according to the third embodiment. FIG. 25 shows a view of an emission surface 308 having a plurality of emission openings 306a to 306d as viewed from a downstream side in a beam traveling direction (z direction). A plurality of emission openings 306a to 306d are formed in the emission surface 308. The plurality of emission openings 306a to 306d can have the same shape and size as the corresponding incidence openings 302a to 302d. The plurality of emission openings 306a to 306d are disposed such that positions in the x direction and the y direction orthogonal to the traveling direction of the scanning beam SB match the incidence openings 302a to 302d. Opening widths w3a, w3b, w3c, w3d of the plurality of emission openings 306a to 306d in the slit width direction may be the same as the opening widths w1a to w1d of the corresponding incidence openings 302a to 302d in the slit width direction. Opening widths w4a, w4b, w4c, w4d of the plurality of emission openings 306a to 306d in the slit length direction may be the same as the opening widths w2a to w2d of the corresponding incidence openings 302a to 302d in the slit length direction.

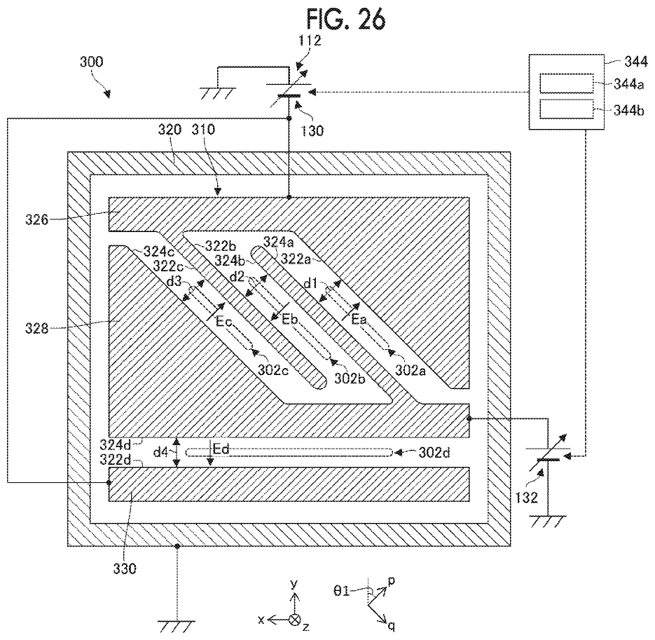

FIG. 26 is a cross-sectional view showing a schematic configuration of an electrode assembly 310 according to the third embodiment. The electrode assembly 310 is disposed between the incidence surface 304 and the emission surface 308. In FIG. 26, positions of the plurality of incidence openings 302a to 302d are indicated by broken lines.

The electrode assembly 310 includes a first electrode surface 322a, a second electrode surface 324a, a third electrode surface 324b, a fourth electrode surface 322b, a fifth electrode surface 322c, a sixth electrode surface 324c, a seventh electrode surface 324d, and an eighth electrode surface 322d. The first electrode surface 322a to the sixth electrode surface 324c can be configured in the same manner as the sixth electrode surface 224c from the first electrode surface 222a shown in FIG. 21 described above. The seventh electrode surface 324d and the eighth electrode surface 322d face each other in a fourth direction at a fourth distance d4 across the ion beam from the fourth incidence opening 302d toward the fourth emission opening 306d. The fourth direction is parallel to the slit width direction (y direction) of the fourth incidence opening 302d. In the example shown in FIG. 26, the fourth direction is oblique to the first direction, the second direction, and the third direction. The fourth distance d4 is the same as the first distance d1, the second distance d2, and the third distance d3.

The power supply 112 is connected to the electrode assembly 310. The power supply 112 is configured in the same manner as in the above-described embodiment. The power supply 112 generates a potential difference between two electrode surfaces facing each other. The power supply 112 generates a first potential difference between the first electrode surface 322a and the second electrode surface 324a, generates a second potential difference between the third electrode surface 324b and the fourth electrode surface 322b, generates a third potential difference between the fifth electrode surface 322c and the sixth electrode surface 324c, and generates a fourth potential difference between the seventh electrode surface 324d and the eighth electrode surface 322d.

The electrode assembly 310 includes a first electrode body 326, a second electrode body 328, and a third electrode body 330. The first electrode body 326 has the first electrode surface 322a, the fourth electrode surface 322b, and the fifth electrode surface 322c. The second electrode body 328 has the second electrode surface 324a, the third electrode surface 324b, the sixth electrode surface 324c, and the seventh electrode surface 324d. The third electrode body 330 has the eighth electrode surface 322d. The first power supply 130 is coupled to the first electrode body 326 and the third electrode body 330, and the second power supply 132 is coupled to the second electrode body 328. In this case, the magnitudes of the first potential difference, the second potential difference, the third potential difference, and the fourth potential difference are the same. However, the directions of the electric fields generated between the two facing electrode surfaces may be different. A direction of a first electric field Ea based on the first potential difference between the first electrode surface 322a and the second electrode surface 324a is the same as a direction of a third electric field Ec based on the third potential difference between the fifth electrode surface 322c and the sixth electrode surface 324c, but is opposite (or antiparallel) to a direction of a second electric field Eb based on the second potential difference between the third electrode surface 324b and the fourth electrode surface 322b. A direction of a fourth electric field Ed based on the fourth potential difference between the seventh electrode surface 324d and the eighth electrode surface 322d is oblique to the directions of the first electric field Ea, the second electric field Eb, and the third electric field Ec.

A side plate 320 for surrounding the first electrode body 326, the second electrode body 328, and the third electrode body 330 can be provided around the electrode assembly 310. The side plate 320 can be configured to extend in a tubular shape from the front panel 316 toward the back panel 318. The front panel 316, the back panel 318, and the side plate 320 can constitute a housing that accommodates the electrode assembly 310. The front panel 316, the back panel 318, and the side plate 320 can be grounded to have a ground potential.

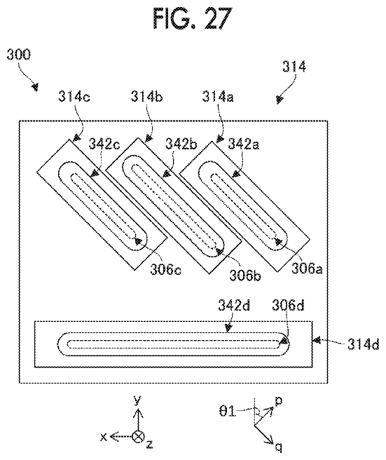

FIG. 27 is a plan view showing a schematic configuration of a current measurement device 314 according to the third embodiment. The current measurement device 314 includes a plurality of current measurement devices 314a, 314b, 314c, 314d. The plurality of current measurement devices 314a to 314d are configured to detect the ion beam passing through the corresponding emission openings 306a to 306d to measure the beam current value. In FIG. 27, positions of the plurality of emission openings 306a to 306d are indicated by broken lines.

The current measurement device 314 can include a first current measurement device 314a, a second current measurement device 314b, a third current measurement device 314c, and a fourth current measurement device 314d. The first current measurement device 314a detects the ion beam emitted from the first emission opening 306a to measure the first beam current value. The second current measurement device 314b detects the ion beam emitted from the second emission opening 306b to measure the second beam current value. The third current measurement device 314c detects the ion beam emitted from the third emission opening 306c to measure the third beam current value. The fourth current measurement device 314d detects the ion beam emitted from the fourth emission opening 306d to measure the fourth beam current value.

Each of the plurality of current measurement devices 314a to 314d can be configured in the same manner as the current measurement device 114 according to the first embodiment described above. Each of the plurality of current measurement devices 314a to 314d can include a Faraday cup, an ammeter coupled to the Faraday cup, a suppression electrode having through openings 342a, 342b, 342c, 342d, and a suppression power supply coupled to the suppression electrode.

The angle measurement device 300 can further include a measurement controller 344 (see FIG. 26). The measurement controller 344 includes a processor 344a and a memory 344b. The measurement controller 344 can be configured in the same manner as the measurement controller 144 according to the first embodiment described above. The measurement controller 344 outputs a command value for applying a variable voltage to the electrode assembly 310, and changes the potential difference ΔV between the two facing electrode surfaces over time.

The measurement controller 344 acquires the beam current values measured by the plurality of current measurement devices 314a to 314d, and calculates the angle information using the acquired beam current values. The measurement controller 344 totals, for example, the first beam current value Ii1, the second beam current value Ii2, and the third beam current value Ii3 measured for a specific potential difference ΔVi, and calculates the intensity of the angle component in the p direction using the total beam current value Ii (=Ii1+Ii2+Ii3). The measurement controller 344 can obtain the beam current value Ii at the angle θpi by converting the potential difference ΔVi into the angle θpi in the p direction. As a result, the angle information in the p direction oblique to the scanning direction (y direction) can be obtained.

The measurement controller 344 acquires the fourth beam current value Ii4 measured for a specific potential difference ΔVi, and calculates the intensity of the angle component in the y direction using the fourth beam current value Ii4. The measurement controller 344 can obtain the beam current value Ii4 at the angle θyi by converting the potential difference ΔVi into the angle θyi. As a result, the angle information in the scanning direction (y direction) can be obtained.

The measurement controller 344 calculates the angle information in the direction (x direction) orthogonal to the scanning direction using the angle information in the scanning direction (y direction) and the angle information in the p direction oblique to the scanning direction (y direction). As a method of calculating the angle information in the direction (x direction) orthogonal to the scanning direction, for example, a known method described in JP2019-169407A can be used.

In the third embodiment, the current measurement device 314 may use a single current measurement device in place of the first current measurement device 314a to the third current measurement device 314c. In this case, the current measurement device 314 may include a first current measurement device that totals and detects the plurality of ion beams emitted from each of the first emission opening 306a to the third emission opening 306c to measure the first beam current value, and a second current measurement device that detects the ion beam emitted from the fourth emission opening 306d to measure the second beam current value. The first current measurement device is configured to detect an ion beam group consisting of all of the ion beam emitted from the first emission opening 306a, the ion beam emitted from the second emission opening 306b, and the ion beam emitted from the third emission opening 306c. In this case, the total value Ii (=Ii1+Ii2+Ii3) of the first beam current value Ii1, the second beam current value Ii2, and the third beam current value Ii3 can be measured using the first current measurement device.

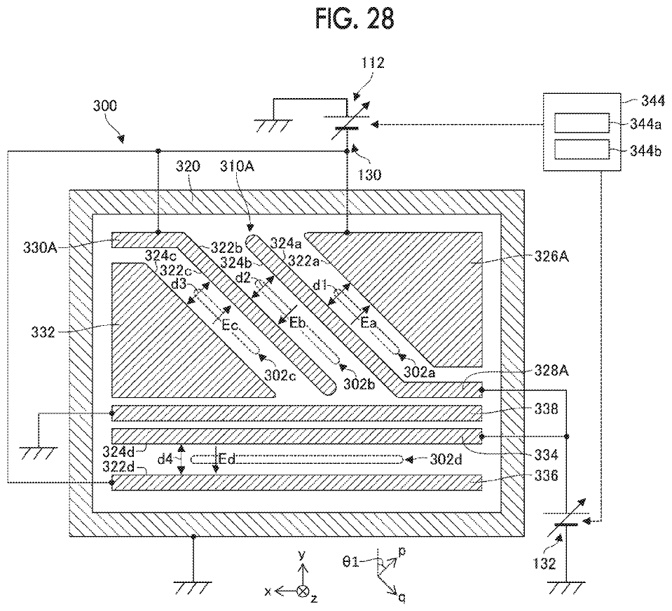

FIG. 28 is a cross-sectional view showing a schematic configuration of an electrode assembly 310A according to the modification example. The electrode assembly 310A includes a first electrode surface 322a, a second electrode surface 324a, a third electrode surface 324b, a fourth electrode surface 322b, a fifth electrode surface 322c, a sixth electrode surface 324c, a seventh electrode surface 324d, and an eighth electrode surface 322d, as in the electrode assembly 310 shown in FIG. 26 described above.

The electrode assembly 310A includes a first electrode body 326A having the first electrode surface 322a, a second electrode body 328A having the second electrode surface 324a and the third electrode surface 324b, a third electrode body 330A having the fourth electrode surface 322b and the fifth electrode surface 322c, a fourth electrode body 332 having the sixth electrode surface 324c, a fifth electrode body 334 having the seventh electrode surface 324d, and a sixth electrode body 336 having the eighth electrode surface 322d. The first power supply 130 is coupled to the first electrode body 326A, the third electrode body 330A, and the sixth electrode body 336. The second power supply 132 is coupled to the second electrode body 328A, the fourth electrode body 332, and the fifth electrode body 334. The power supply coupled to each of the fifth electrode body 334 and the sixth electrode body 336 may be reversed, and the first power supply 130 may be coupled to the fifth electrode body 334 and the second power supply 132 may be coupled to the sixth electrode body 336.

The electrode assembly 310A further includes a seventh electrode body 338. The seventh electrode body 338 is disposed between an electrode group including the first electrode body 326A, the second electrode body 328A, the third electrode body 330A, and the fourth electrode body 332, and the fifth electrode body 334. The seventh electrode body 338 is grounded to have a ground potential.

Even in a case in which the electrode assembly 310A according to the present modification example is used, the same effect as that of the third embodiment described above can be achieved.

Aspects of the present disclosure are as follows.

### Aspect 1

An ion implanter including: a beam scanner configured to perform reciprocating scanning in a predetermined scanning direction with an ion beam to generate a scanning beam; and an angle measurement device that measures angle information of the scanning beam, in which the angle measurement device includes an incidence surface including a first incidence opening into which the scanning beam is incident, an emission surface provided with a first emission opening from which an ion beam that has passed through the first incidence opening is emitted, an electrode assembly provided between the incidence surface and the emission surface and including a first electrode surface and a second electrode surface that face each other in a first direction across an ion beam directed from the first incidence opening toward the first emission opening, a power supply that applies a voltage to the electrode assembly to generate a potential difference between the first electrode surface and the second electrode surface, and a current measurement device that detects the ion beam that has passed through the first emission opening to measure a beam current value.

### Aspect 2

The ion implanter according to aspect 1, in which each of the first incidence opening and the first emission opening is a slit having a slit width direction parallel to the first direction.

### Aspect 3

The ion implanter according to aspect 1 or 2, in which the first direction is parallel to the scanning direction.

### Aspect 4

The ion implanter according to aspect 1 or 2, in which the first direction is oblique to the scanning direction.

### Aspect 5

The ion implanter according to any one of aspects 1 to 4, in which the angle measurement device further includes a processor that calculates the angle information of the scanning beam using a value of the potential difference between the first electrode surface and the second electrode surface and a beam current value measured by the current measurement device.

### Aspect 6

The ion implanter according to aspect 5, in which the power supply applies a variable voltage to the electrode assembly, and the processor calculates the angle information of the scanning beam using a time-series value of the potential difference between the first electrode surface and the second electrode surface and a time-series value of a beam current measured by the current measurement device.

### Aspect 7

The ion implanter according to any one of aspects 1 to 6, in which the beam scanner generates the scanning beam scanned with a first frequency, and the power supply applies a voltage that is periodically changed at a second frequency different from the first frequency to the electrode assembly.

### Aspect 8

The ion implanter according to aspect 7, in which the second frequency is 10 times or more and 1000 times or less of the first frequency, or the second frequency is one-thousandth or more and one-tenth or less of the first frequency.

### Aspect 9

The ion implanter according to any one of aspects 1 to 8, in which the incidence surface further includes a second incidence opening, the emission surface further includes a second emission opening, the electrode assembly further includes a third electrode surface and a fourth electrode surface that face each other in a second direction across an ion beam directed from the second incidence opening toward the second emission opening, the power supply generates a potential difference between the third electrode surface and the fourth electrode surface, and the current measurement device includes a first current measurement device that detects an ion beam that has passed through the first emission opening to measure a first beam current value, and a second current measurement device that detects an ion beam that has passed through the second emission opening to measure a second beam current value.

### Aspect 10

The ion implanter according to any one of aspects 1 to 8, in which the incidence surface further includes a second incidence opening, the emission surface further includes a second emission opening, the electrode assembly further includes a third electrode surface and a fourth electrode surface that face each other in a second direction across an ion beam directed from the second incidence opening toward the second emission opening, the power supply generates a potential difference between the third electrode surface and the fourth electrode surface, and the current measurement device further detects the ion beam that has passed through the second emission opening to measure the beam current value.

### Aspect 11

The ion implanter according to aspect 9 or 10, in which the electrode assembly includes a first electrode body that includes the first electrode surface, a second electrode body that includes the second electrode surface and the third electrode surface, and a third electrode body that includes the fourth electrode surface.

### Aspect 12

The ion implanter according to aspect 9 or 10, in which the electrode assembly includes a first electrode body that includes the first electrode surface and the fourth electrode surface, and a second electrode body that includes the second electrode surface and the third electrode surface.

### Aspect 13

The ion implanter according to aspect 9 or 10, in which the second incidence opening and the second emission opening are slits each having a slit width direction parallel to the second direction.

### Aspect 14

The ion implanter according to any one of aspects 9 to 13, in which the second direction is parallel to the first direction.

### Aspect 15

The ion implanter according to any one of aspects 9 to 13, in which the second direction is oblique to the first direction.

### Aspect 16

The ion implanter according to aspect 9, in which the incidence surface further includes a third incidence opening, the emission surface further includes a third emission opening, the electrode assembly further includes a fifth electrode surface and a sixth electrode surface that face each other in a third direction across an ion beam directed from the third incidence opening toward the third emission opening, the power supply generates a potential difference between the fifth electrode surface and the sixth electrode surface, and the current measurement device further includes a third current measurement device that detects the ion beam that has passed through the third emission opening to measure a third beam current value.

### Aspect 17

The ion implanter according to aspect 10, in which the incidence surface further includes a third incidence opening, the emission surface further includes a third emission opening, the electrode assembly further includes a fifth electrode surface and a sixth electrode surface that face each other in a third direction across an ion beam directed from the third incidence opening toward the third emission opening, the power supply generates a potential difference between the fifth electrode surface and the sixth electrode surface, and the current measurement device includes a first current measurement device that detects an ion beam that has passed through the first emission opening and an ion beam that has passed through the second emission opening to measure a first beam current value, and a second current measurement device that detects an ion beam that has passed through the third emission opening to measure a second beam current value.

### Aspect 18

The ion implanter according to aspect 10, in which the incidence surface further includes a third incidence opening, the emission surface further includes a third emission opening, the electrode assembly further includes a fifth electrode surface and a sixth electrode surface that face each other in a third direction across an ion beam directed from the third incidence opening toward the third emission opening, the power supply generates a potential difference between the fifth electrode surface and the sixth electrode surface, and the current measurement device further detects the ion beam that has passed through the third emission opening to measure the beam current value.

### Aspect 19

The ion implanter according to any one of aspects 16 to 18, in which the third direction is parallel to the first direction and the second direction, and the electrode assembly includes a first electrode body having the first electrode surface, the fourth electrode surface, and the fifth electrode surface, and a second electrode body having the second electrode surface, the third electrode surface, and the sixth electrode surface.

### Aspect 20

The ion implanter according to aspect 16 or 17, in which the second direction is parallel to the first direction, the third direction is oblique to the first direction and the second direction, and the electrode assembly includes a first electrode body that includes the first electrode surface, the fourth electrode surface, and the fifth electrode surface, a second electrode body that includes the second electrode surface and the third electrode surface, and a third electrode body that includes the sixth electrode surface.

### Aspect 21

The ion implanter according to aspect 16 or 17, in which the second direction is parallel to the first direction, the third direction is oblique to the first direction and the second direction, and the electrode assembly includes a first electrode body that includes the first electrode surface, a second electrode body that includes the second electrode surface and the third electrode surface, a third electrode body that includes the fourth electrode surface, a fourth electrode body that includes the fifth electrode surface, a fifth electrode body that includes the sixth electrode surface, and a sixth electrode body that is provided between an electrode group including the first electrode body, the second electrode body, and the third electrode body and the fourth electrode body.

### Aspect 22

An angle measurement device including: an incidence surface that includes a first incidence opening and a second incidence opening into which an ion beam is incident; an emission surface that includes a first emission opening from which an ion beam that has passed through the first incidence opening is emitted and a second emission opening from which an ion beam that has passed through the second incidence opening is emitted; an electrode assembly that is provided between the incidence surface and the emission surface, and that includes a first electrode surface and a second electrode surface that face each other in a first direction across an ion beam directed from the first incidence opening toward the first emission opening, and a third electrode surface and a fourth electrode surface that face each other in a second direction across an ion beam directed from the second incidence opening toward the second emission opening, and that includes an electrode body including the second electrode surface and the third electrode surface; a power supply that applies a voltage to the electrode assembly to generate a potential difference between the first electrode surface and the second electrode surface, and a potential difference between the third electrode surface and the fourth electrode surface; and a current measurement device that detects at least one of an ion beam that has passed through the first emission opening and an ion beam that has passed through the second emission opening to measure a beam current value.

Hitherto, the present disclosure has been described with reference to each of the above-described embodiments. However, the present disclosure is not limited to each of the above-described embodiments. The configurations of each of the embodiments may appropriately be combined or replaced with each other. Further, it is also possible to appropriately rearrange combinations in each embodiment or the order of the processing, and to add modifications, such as various design changes, to the embodiments, based on the knowledge of those skilled in the art. The scopes of the ion implanter and the ion implantation method according to the embodiments of the present disclosure may also include embodiments to which such rearrangements or modifications are added.

The embodiments according to the present disclosure may adopt a form of a computer program including one or more computer-readable sequences for describing the methods according to the present disclosure, or may adopt a form of a non-transitory and tangible recording medium (for example, a non-volatile memory, a magnetic tape, a magnetic disk, or an optical disk) storing such a computer program. The processor may realize the method according to the present disclosure by executing the computer program.

According to the non-limiting exemplary embodiment of the present disclosure, it is possible to provide a technique for accurately and quickly measuring angle information of an ion beam.

It should be understood that the invention is not limited to the above-described embodiment, but may be modified into various forms on the basis of the spirit of the disclosure. Additionally, the modifications are included in the scope of the disclosure.

What is claimed is:

1. An ion implanter comprising:
a beam scanner configured to perform reciprocating scanning in a predetermined scanning direction with an ion beam to generate a scanning beam; and
an angle measurement device that measures angle information of the scanning beam,
wherein the angle measurement device includes
an incidence surface including a first incidence opening into which the scanning beam is incident,
an emission surface provided with a first emission opening from which an ion beam that has passed through the first incidence opening is emitted,
an electrode assembly provided between the incidence surface and the emission surface and including a first electrode surface and a second electrode surface that face each other in a first direction across an ion beam directed from the first incidence opening toward the first emission opening,
a power supply that applies a voltage to the electrode assembly to generate a potential difference between the first electrode surface and the second electrode surface, and
a current measurement device that detects the ion beam that has passed through the first emission opening to measure a beam current value.

2. The ion implanter according to claim 1,
wherein each of the first incidence opening and the first emission opening is a slit having a slit width direction parallel to the first direction.

3. The ion implanter according to claim 1,
wherein the first direction is parallel to the scanning direction.

4. The ion implanter according to claim 1,
wherein the first direction is oblique to the scanning direction.

5. The ion implanter according to claim 1,
wherein the angle measurement device further includes a processor that calculates the angle information of the scanning beam using a value of the potential difference between the first electrode surface and the second electrode surface and a beam current value measured by the current measurement device.

6. The ion implanter according to claim 5,
wherein the power supply applies a variable voltage to the electrode assembly, and
the processor calculates the angle information of the scanning beam using a time-series value of the potential difference between the first electrode surface and the second electrode surface and a time-series value of a beam current measured by the current measurement device.

7. The ion implanter according to claim 1,
wherein the beam scanner generates the scanning beam scanned with a first frequency, and
the power supply applies a voltage that is periodically changed at a second frequency different from the first frequency to the electrode assembly.

8. The ion implanter according to claim 7,
wherein the second frequency is 10 times or more and 1000 times or less of the first frequency, or
the second frequency is one-thousandth or more and one-tenth or less of the first frequency.

9. The ion implanter according to claim 1,
wherein the incidence surface further includes a second incidence opening,
the emission surface further includes a second emission opening,
the electrode assembly further includes a third electrode surface and a fourth electrode surface that face each other in a second direction across an ion beam directed from the second incidence opening toward the second emission opening,
the power supply generates a potential difference between the third electrode surface and the fourth electrode surface, and
the current measurement device includes a first current measurement device that detects an ion beam that has passed through the first emission opening to measure a first beam current value, and a second current measurement device that detects an ion beam that has passed through the second emission opening to measure a second beam current value.

10. The ion implanter according to claim 1,
wherein the incidence surface further includes a second incidence opening,
the emission surface further includes a second emission opening,
the electrode assembly further includes a third electrode surface and a fourth electrode surface that face each other in a second direction across an ion beam directed from the second incidence opening toward the second emission opening,
the power supply generates a potential difference between the third electrode surface and the fourth electrode surface, and
the current measurement device further detects the ion beam that has passed through the second emission opening to measure the beam current value.

11. The ion implanter according to claim 9,
wherein the electrode assembly includes a first electrode body that includes the first electrode surface, a second electrode body that includes the second electrode surface and the third electrode surface, and a third electrode body that includes the fourth electrode surface.

12. The ion implanter according to claim 9,
wherein the electrode assembly includes a first electrode body that includes the first electrode surface and the fourth electrode surface, and a second electrode body that includes the second electrode surface and the third electrode surface.

13. The ion implanter according to claim 9,
wherein the second incidence opening and the second emission opening are slits each having a slit width direction parallel to the second direction.

14. The ion implanter according to claim 9,
wherein the second direction is parallel to the first direction.

15. The ion implanter according to claim 9,
wherein the second direction is oblique to the first direction.

16. The ion implanter according to claim 9,
wherein the incidence surface further includes a third incidence opening,
the emission surface further includes a third emission opening,
the electrode assembly further includes a fifth electrode surface and a sixth electrode surface that face each other in a third direction across an ion beam directed from the third incidence opening toward the third emission opening,
the power supply generates a potential difference between the fifth electrode surface and the sixth electrode surface, and
the current measurement device further includes a third current measurement device that detects the ion beam that has passed through the third emission opening to measure a third beam current value.

17. The ion implanter according to claim 10,
wherein the incidence surface further includes a third incidence opening,
the emission surface further includes a third emission opening,
the electrode assembly further includes a fifth electrode surface and a sixth electrode surface that face each other in a third direction across an ion beam directed from the third incidence opening toward the third emission opening,
the power supply generates a potential difference between the fifth electrode surface and the sixth electrode surface, and
the current measurement device includes a first current measurement device that detects an ion beam that has passed through the first emission opening and an ion beam that has passed through the second emission opening to measure a first beam current value, and a second current measurement device that detects an ion beam that has passed through the third emission opening to measure a second beam current value.

18. The ion implanter according to claim 10,
wherein the incidence surface further includes a third incidence opening,
the emission surface further includes a third emission opening,
the electrode assembly further includes a fifth electrode surface and a sixth electrode surface that face each other in a third direction across an ion beam directed from the third incidence opening toward the third emission opening,
the power supply generates a potential difference between the fifth electrode surface and the sixth electrode surface, and
the current measurement device further detects the ion beam that has passed through the third emission opening to measure the beam current value.

19. The ion implanter according to claim 16,
wherein the third direction is parallel to the first direction and the second direction, and the electrode assembly includes a first electrode body including the first electrode surface, the fourth electrode surface, and the fifth electrode surface, and a second electrode body including the second electrode surface, the third electrode surface, and the sixth electrode surface.

20. The ion implanter according to claim 16,
wherein the second direction is parallel to the first direction,
the third direction is oblique to the first direction and the second direction, and
the electrode assembly includes a first electrode body that includes the first electrode surface, the fourth electrode surface, and the fifth electrode surface, a second electrode body that includes the second electrode surface and the third electrode surface, and a third electrode body that includes the sixth electrode surface.

21. The ion implanter according to claim 16,
wherein the second direction is parallel to the first direction,
the third direction is oblique to the first direction and the second direction, and
the electrode assembly includes a first electrode body that includes the first electrode surface, a second electrode body that includes the second electrode surface and the third electrode surface, a third electrode body that includes the fourth electrode surface, a fourth electrode body that includes the fifth electrode surface, a fifth electrode body that includes the sixth electrode surface, and a sixth electrode body that is provided between an electrode group including the first electrode body, the second electrode body, and the third electrode body and the fourth electrode body.

22. An angle measurement device comprising:
an incidence surface that includes a first incidence opening and a second incidence opening into which an ion beam is incident;
an emission surface that includes a first emission opening from which an ion beam that has passed through the first incidence opening is emitted and a second emission opening from which an ion beam that has passed through the second incidence opening is emitted;
an electrode assembly that is provided between the incidence surface and the emission surface, and that includes a first electrode surface and a second electrode surface that face each other in a first direction across an ion beam directed from the first incidence opening toward the first emission opening, and a third electrode surface and a fourth electrode surface that face each other in a second direction across an ion beam directed from the second incidence opening toward the second emission opening, and that includes an electrode body including the second electrode surface and the third electrode surface;
a power supply that applies a voltage to the electrode assembly to generate a potential difference between the first electrode surface and the second electrode surface, and a potential difference between the third electrode surface and the fourth electrode surface; and
a current measurement device that detects at least one of an ion beam that has passed through the first emission opening and an ion beam that has passed through the second emission opening to measure a beam current value.
